(19) United States
(12) Patent Application Publication
(10) Pub. No.: US 2026/0333642 A1
(43) Pub. Date: Oct. 22, 2026

(54) HYBRID BOTTOM MOUNTING OF CAGES ON COLD PLATES

(71) Applicant: MELLANOX TECHNOLOGIES, LTD., Yokneam (IL)

(72) Inventors: Shay Zaretsky, Kiryat Motzkin (IL); Rom Becker, Ramat Yishai (IL); Oren Weltsch, Eli-ad (IL); Itamar Bartal, Yokneam Illit (IL); Kfir Katz, Tivon (IL); Eli Zatulovski, Nesher (IL); Nir Einati, Raanana (IL); Peter Breitman, Atlit (IL)

(21) Appl. No.: 19/184,341

(22) Filed: Apr. 21, 2025

(51) Int. Cl. H05K 7/20

(52) U.S. Cl. CPC H05K 7/20772

(57) ABSTRACT

A system, switch, and liquid-cooled switch are described. An illustrative liquid-cooled switch is described to include one or more cages configured to receive a pluggable transceiver module. The liquid-cooled switch may further include a cold plate attached to the one or more cages, where the one or more cages are attached to the cold plate with one or more fasteners and where the cold plate includes one or more conduits through which a heat transfer fluid is allowed to pass.

### BACKGROUND

The present disclosure is generally directed to networking devices, networking device assemblies, and assemblies for liquid-cooled switches.

Data centers are the storage and data processing hubs of the Internet. Cable assemblies are used to interconnect network devices and/or network switches within a data center to enable high-speed communication between the network switches.

### GENERAL DESCRIPTION

A problem often encountered in many data centers is the problem related to heat management and heat evacuation. In particular, many devices within a data center operate at high speeds, which causes the devices to generate a large amount of heat. One particular problem relates to a problem of inefficient heat evacuation from the bottom side of receptacles in High Performance Computing (HPC) environments. The focus may be on high-power density components such as processors and other computing circuitry, including graphics processing units (GPUs), central processing units (CPUs), data processing units (DPUs), memory, switches, and power regulators. While it may be possible to provide solutions for heat transfer away from such receptacles, the problem becomes complicated due to varying tolerances of different parts within and around the optical transceiver module. Specifically, but without limitation, the varying tolerances may be present due to the connection of a Printed Circuit Board (PCB) to copper to maximize the thermal contact area between the cold plate and cage. Thus, while it may be desirable to support particular configurations (e.g., belly-to-belly interconnect cage configurations) for such receptacles to support efficient cable management and space utilization, the implementation of space-efficient configurations creates other problems for heat management and tolerance support.

Previous solutions primarily employed press-fit mounting methods, which required high precision and often proved challenging to assemble and maintain. These configurations also lacked flexibility in tolerance accommodation, leading to increased manufacturing complexity and potential assembly defects.

Embodiments of the present disclosure aim to address the above-noted problems associated with receptacles and the switches in which the receptacles are deployed. In particular, and without limitation, embodiments of the present disclosure aim to solve one or more of the above-noted problems by introducing a hybrid bottom mounting technique for cages on cold plates with and embedded Printed Circuit Board (PCB). In some embodiments, the proposed technique employs screws or other suitable fasteners for attaching the cages to the cold plates, significantly simplifying the assembly process and reducing the precision required for the overall assembly. Additionally, embodiments of the present disclosure contemplate the use of press-fit connections in the signal area to ensure robust electrical and signal connectivity. In some embodiments, the hybrid fastening process, combining screws in the cold plate area with press-fit for the signal, enables attachment of a static cold plate to various tolerance parts while supporting belly-to-belly interconnect cage configurations.

According to at least some embodiments, a Thermal Interface Material (TIM) may be placed between the cage and cold plate to enhance thermal transfer between the components. This design allows for efficient heat evacuation, accommodates varying tolerances, and enables space saving configurations, such as belly-to-belly interconnect configurations.

In one embodiment, a system is provided that includes: one or more cages; and a cold plate attached to the one or more cages, where the one or more cages are attached to the cold plate with one or more fasteners.

In some aspects, the cold plate includes one or more conduits through which a heat transfer fluid is allowed to pass.

In some aspects, the one or more fasteners include a screw.

In some aspects, the system further includes a TIM placed between the one or more cages and the cold plate. The TIM may include at least one of a grease, elastomeric pad, tape, film, phase change material, gel, adhesive, and paste.

In some aspects, the one or more cages include a plurality of cages.

In some aspects, the one or more cages are provided on a front panel of a network device and are configured to accept a pluggable transceiver module therein.

In some aspects, the network device includes at least one of a switch and a network adapter and the pluggable transceiver module includes a connector plug. The connector plug may include at least one of a QSFP plug and an OSFP plug.

In some aspects, the system further includes a PCB provided in the cold plate. The PCB may be press-fit into a recess of the cold plate.

In some aspects, the one or more cages include a top cage and a bottom cage and the cold plate is sandwiched between the top cage and the bottom cage. The top cage and the bottom cage may be provided in a belly-to-belly configuration.

In an illustrative embodiment, a network device is provided that includes: one or more cages configured to receive a pluggable transceiver module; and a cold plate attached to the one or more cages in an arrangement that facilitates a transfer of heat away from the one or more cages.

In some aspects, the cold plate includes one or more conduits through which a heat transfer fluid is allowed to pass.

In some aspects, the network device further includes a PCB embedded in a recess of the cold plate.

In some aspects, the cold plate is screwed to the one or more cages.

In some aspects, the one or more cages are provided at a front panel.

In some aspects, the pluggable transceiver module includes at least one of a QSFP plug and an OSFP plug.

In some aspects, a back of the cold plate extends beyond a back of the one or more cages.

In some aspects, the one or more cages include a top cage and a bottom cage and the cold plate is sandwiched between the top cage and the bottom cage.

In an illustrative embodiment, a liquid-cooled switch is provided that includes: one or more cages configured to receive a pluggable transceiver module; and a cold plate attached to the one or more cages, where the one or more cages are attached to the cold plate with one or more fasteners and where the cold plate comprises one or more conduits through which a heat transfer fluid is allowed to pass.

In some aspects, the one or more fasteners include a screw, the one or more conduits include a plurality of conduits, and the one or more fasteners are positioned between the plurality of conduits.

In some aspects, the liquid-cooled switch further includes a PCB embedded in a recess of the cold plate, where the PCB is press-fit into the recess of the cold plate.

In some aspects, the pluggable transceiver module includes at least one of a QSFP plug and an OSFP plug.

In some aspects, the cold plate is bottom-mounted to the one or more cages thereby facilitating an efficient heat evacuation therefrom.

In an illustrative embodiment, a switch is provided that includes: one or more receptacles configured to exchange data via optical signals; and a cold plate attached to a bottom side of the one or more receptacles with one or more fasteners such that the cold plate facilitates a transfer of heat away from the one or more receptacles.

In some aspects, the one or more receptacles include an opening to receive a pluggable transceiver module.

In some aspects, the one or more receptacles are included in a top cage and a bottom cage and the cold plate is sandwiched between the top cage and the bottom cage.

In some aspects, the top cage and the bottom cage are connected to the cold plate in a belly-to-belly configuration.

In some aspects, the switch further includes a PCB embedded in a recess of the cold plate, where the PCB is press-fit into the recess of the cold plate, and where the cold plate is manufactured with a different tolerance than the PCB.

Numerous additional features and advantages are described herein and will be apparent to those skilled in the art upon consideration of the following Detailed Description and in view of the figures.

### BRIEF DESCRIPTION OF THE SEVERAL VIEWS OF THE DRAWINGS

The accompanying drawings are incorporated into and form a part of the specification to illustrate several examples of the present disclosure. These drawings, together with the description, explain the principles of the disclosure. The drawings simply illustrate preferred and alternative examples of how the disclosure can be made and used and are not to be construed as limiting the disclosure to only the illustrated and described examples. Further features and advantages will become apparent from the following, more detailed, description of the various aspects, embodiments, and configurations of the disclosure, as illustrated by the drawings referenced below.

FIG. 1A shows a perspective view of a system in accordance with embodiments of the present disclosure;

FIG. 1B shows a perspective view of additional components of a system in accordance with embodiments of the present disclosure;

FIG. 1C shows a perspective view of a cold plate provided as part of a system in accordance with embodiments of the present disclosure;

FIG. 2 provides a top perspective view of a cold plate with one or more cages attached thereto in accordance with embodiments of the present disclosure;

FIG. 3 illustrates details of a TIM provided on a cold plate in accordance with embodiments of the present disclosure;

FIG. 4 illustrates details of the system without the cold plate in accordance with embodiments of the present disclosure;

FIG. 5A provides a top perspective view of the cold plate in accordance with embodiments of the present disclosure;

FIG. 5B provides a detailed view of a portion of the cold plate in accordance with embodiments of the present disclosure;

FIG. 6 illustrates details of a PCB in accordance with embodiments of the present disclosure;

FIG. 7A provides a top perspective view of a set of cages in accordance with embodiments of the present disclosure;

FIG. 7B provides a bottom perspective view of a set of cages in accordance with embodiments of the present disclosure;

FIG. 7C provides a detailed view of a cage in a set of cages in accordance with embodiments of the present disclosure;

FIG. 7D provides a detailed view of a fastener in accordance with embodiments of the present disclosure;

FIG. 8 provides a detailed view of a manifold used to carry a heat transfer fluid to and/or from the cold plate in accordance with embodiments of the present disclosure;

FIG. 9 illustrates an example data center in accordance with embodiments of the present disclosure;

FIG. 10 illustrates a computer system in accordance with embodiments of the present disclosure;

FIG. 11 illustrates a transceiver in accordance with embodiments of the present disclosure;

FIG. 12 illustrates a system that facilitates QKD connectivity in accordance with embodiments of the present disclosure;

FIG. 13 illustrates a system that facilitates QKD communication in accordance with embodiments of the present disclosure;

FIG. 14 illustrates a computer system in accordance with embodiments of the present disclosure;

FIG. 15 illustrates a computer system in accordance with embodiments of the present disclosure;

FIG. 16 illustrates a system including a NIC for facilitating communication within a network in accordance with embodiments of the present disclosure;

FIG. 17A illustrates a transceiver in accordance with embodiments of the present disclosure;

FIG. 17B illustrates a transceiver in accordance with embodiments of the present disclosure;

FIG. 18A illustrates another example of a data center in accordance with embodiments of the present disclosure;

FIG. 18B illustrates additional details of a data center in accordance with embodiments of the present disclosure;

FIG. 18C illustrates additional details of a data center in accordance with embodiments of the present disclosure;

FIG. 19A is a block diagram illustrated one example of a network topology in accordance with embodiments of the present disclosure;

FIG. 19B is a block diagram illustrating another example of a network topology in accordance with embodiments of the present disclosure; and

FIG. 20 is a perspective view of a data center rack in accordance with embodiments of the present disclosure.

### DETAILED DESCRIPTION

Before any embodiments of the disclosure are explained in detail, it is to be understood that the disclosure is not limited in its application to the details of construction and the arrangement of components set forth in the following description or illustrated in the drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Further, the present disclosure may use examples to illustrate one or more aspects thereof. Unless explicitly stated otherwise, the use or listing of one or more examples (which may be denoted by “for example,” “by way of example,” “e.g.,” “such as,” or similar language) is not intended to and does not limit the scope of the present disclosure.

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of the present disclosure will be described herein with reference to drawings that may be schematic illustrations of idealized configurations.

It is one aspect of the present disclosure to provide a system having one or more cages attached to a cold plate. The cold plate may also have an embedded PCB. The one or more cages may be attached to the cold plate with a fastener, such as a screw, significantly simplifying the assembly process and reducing precision requirements. Additionally, the PCB may be press-fit into the cold plate to ensure robust electrical and signal connectivity. A Thermal Interface Material (TIM) may also be placed between the one or more cages and the cold plate to enhance the thermal transfer between the two.

As described herein, a system may include or be provided as a switch. In particular, a system may include or be provided as a liquid-cooled switch having a number of receptacles. The receptacles may be configured to receive a pluggable network device interface or module of any suitable form factor. While particular form factors are depicted and described herein, it should be appreciated that embodiments of the present disclosure are not so limited. For example, the receptacles may be configured to receive an pluggable transceiver module in the form of a small form factor pluggable (“SFP”), SFP+ plug, quad SFP (“QSFP”) plug, QSFP+ plug, QSFP-double density (“QSFP-DD”) plug, octal SFP (“OSFP”) plug, and/or the like.

It is with respect to the above issues and other problems that the embodiments presented herein were contemplated.

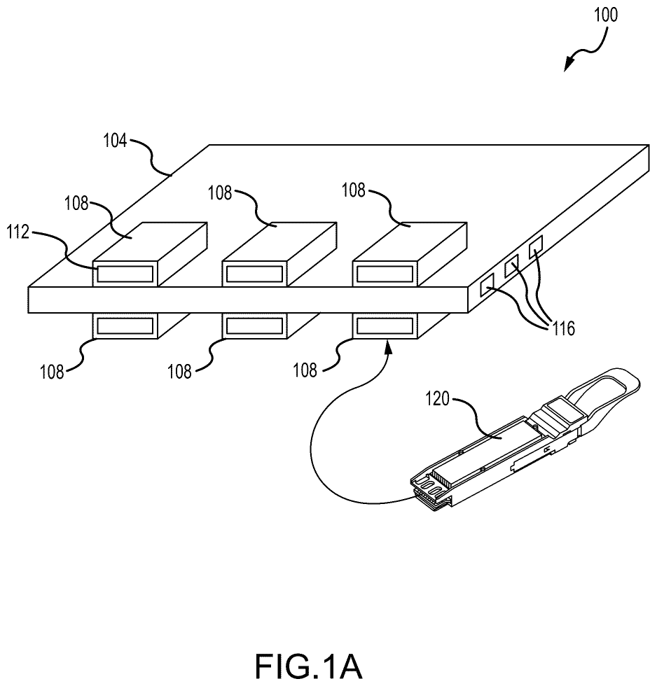

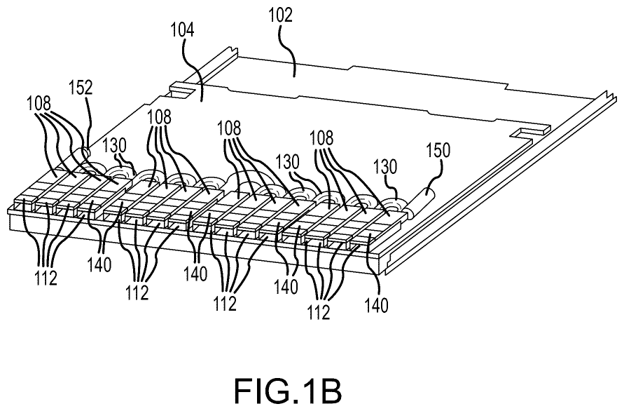

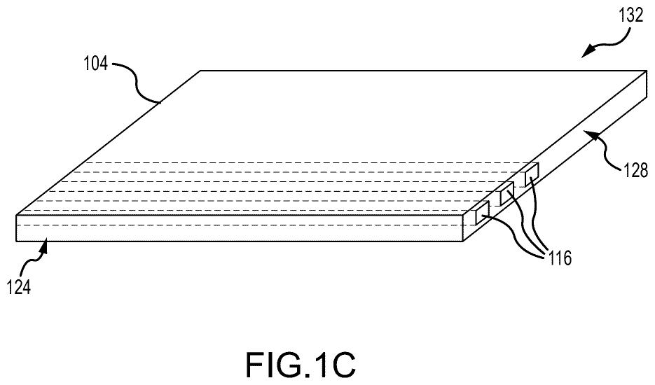

Referring initially to FIGS. 1A-1C, details of a system 100 will be described in accordance with at least some embodiments of the present disclosure. As mentioned above, the system 100 may include or be provided as a switch. Alternatively or additionally, the system 100 or components thereof may be provided as part of a switch, a network adapter such as a Network Interface Controller (NIC), an input/output (I/O) device, other peripheral devices or components on a system-on-chip (SoC), or any other suitable network device. For instance, the system 100 or components thereof may be provided as a blade in a larger rack operating as a switch.

The system 100 is shown to include a cold plate 104 having one or more receptacles 108 attached thereto. The receptacles 108, as will be described in further detail herein, may correspond to or include one or more cages configured to receive an pluggable transceiver module 120. The pluggable transceiver module 120 may include any suitable form factor used in optical or optoelectrical communications. The pluggable transceiver module 120 may be inserted into a receptacle opening 112 of the receptacle 108. Once inserted, electronics within the receptacle 108 may be configured to exchange electrical signals with the pluggable transceiver module 120. In some embodiments, the pluggable transceiver module 120 and receptacle 108 may support machine-to-machine communications in a data center or HPC environment.

FIG. 1B illustrates additional components of a system 100 in accordance with at least some embodiments of the present disclosure. While certain embodiments will be described in connection with a bottom-side cooling of the receptacles 108, it should be appreciated that top-side cooling may alternatively or additionally be used to manage the temperature of the receptacles 108 and other components of the system 100. As an example, and as shown in FIG. 1B, the system 100 may include a housing 102 to accommodate components of the system. The receptacles 108 may be disposed on a substrate, which may include the cold plate 104. In some embodiments, the cold plate 104 may include one or more circuits, in which case the cold plate 104 is or includes a Printed Circuit Board (PCB).

In some embodiments, one, some, or all of the receptacles 108 may receive a network interface device in the form of the pluggable transceiver module 120. Network interface devices or pluggable transceiver modules 120 may, for example, include form factor devices, such as small form factor pluggable (SFP) devices (e.g., quad SFP (QSFP) devices, octal SFP (OSFP) devices) or any other suitable SFP devices known in the art.

While FIG. 1B illustrates sixteen receptacles 108, it should be appreciated that the system 100 may include greater or fewer than sixteen receptacles 108. For example, system 100 may include more than sixteen receptacles 108 (e.g., thirty-two receptacles 108). System 100 may include two or more subgroups of receptacles 108, wherein at least two of the subgroups may be disposed at opposing sides of cold plate 104 with respect to each other.

System 100 may include top-side conduits 130 interconnecting top-side heat sink bodies of the receptacles 108. Conduits 130 may interconnect top-side heat sink bodies in series to each other. A subgroup of top-side heat sink bodies connected in series may be connected to and may receive the liquid coolant from the same liquid coolant source. In the example of FIG. 1B, a subgroup of sixteen in series connected top-side heat sink bodies is connected to the same liquid coolant source. For example, as shown in FIG. 1B, a first top-side heat sink body of top-side heat sink bodies may be connected to an inlet conduit 150 and may receive the liquid coolant from the liquid coolant source. The liquid coolant may flow sequentially through all top-side heat sink bodies in the subgroup and may exit externally from a last heat sink body in the subgroup of top-side heat sink bodies through an outlet conduit 152 connected to the last heat sink body in the subgroup. Inlet conduit 150 and outlet conduit 152 may extend externally from the interior of electronic device 100. Inlet conduit 150 and outlet conduit 152 may be connected to suitable components of a liquid cooling infrastructure within a network data center.

System 100 may also include a plurality of spring clips 140. Each of spring clips 140 may hold one of top-side heat sink bodies with respect to respective receptacles 108. Each of spring clips 140 may hold one of top-side heat sink bodies with respect to respective receptacle 108 while providing a certain measure of movement of respective top-side heat sink body with respect to respective receptacle 108 in a direction that is perpendicular (or substantially perpendicular) to cold plate 104. Spring clips 140 may ensure tight contact of top-side heat sink bodies with the pluggable transceiver module 120 when a pluggable transceiver module 120 is disposed in a receptacle 108. Some of spring clips 140 may be interconnected to hold a subset of top-side heat sink bodies as a single unit with respect to a respective subset of receptacles 108.

The cold plate 104 may include one or more conduits 116 through which a heat transfer fluid is allowed to pass. As can be seen in FIG. 1C, the one or more conduits 116 may pass through an entirety of the cold plate 104. In some examples, the cold plate 104 may include a front surface 124, a back surface 132, and two side surfaces 128 connecting the front surface 124 to the back surface 132. The one or more conduits 116 may be exposed at the side surfaces 128 and may traverse the entire length of the cold plate 104. In some embodiments, the one or more conduits 116 may carry the heat transfer fluid through the structure of the cold plate 104 to support the efficient transfer of heat away from the receptacles 108.

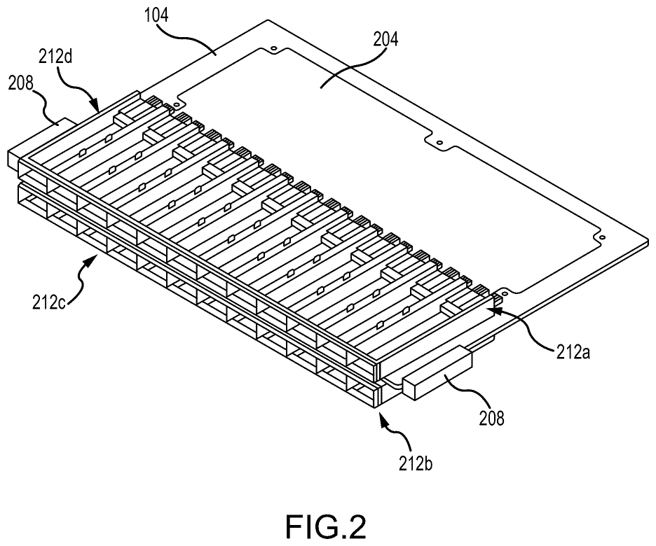

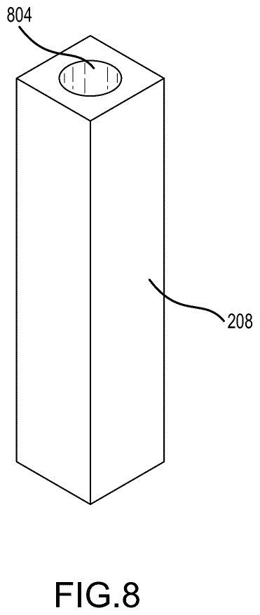

As can be seen in FIG. 2, the cold plate 104 may be connected to one or more manifolds 208 at the side surfaces 128. The manifolds 208 may provide a fluid connectivity between the cold plate 104 and a separate fluid pathway (e.g., a tube or the like). As can be seen in FIG. 8, a manifold 208 may include a fluid passage 804 that provides a fluid pathway between the one or more conduits 116. The manifold 208 may also be configured to be mechanically secured to the cold plate 104 (e.g., in a releasable fashion or in a non-releasable fashion) such that the connection between the fluid passage 804 of the manifold 208 and the one or more conduits 116 is sealed. In this way, heat transfer fluid can be carried to/from the cold plate 104 in an efficient manner and within a closed fluid circuit, thereby avoiding the exposure of electronics in the receptacles 108 to fluid damage. Examples of heat transfer fluid that may flow through the one or more conduits 116 include, without limitation, water, synthetic oil, or molten salt.

FIG. 2 also illustrates that the cold plate 104 may have one or more cages 212a, 212b, 212c, 212d attached thereto. Each of the cages 212a, 212b, 212c, 212d may include one or a plurality of receptacles 108.

The cold plate 104 may be sandwiched between at least two cages. For instance, a first cage 212a may be provided on a top surface of the cold plate 104 and a second cage 212b may be provided on an opposing bottom surface of the cold plate 104. The first cage 212a and the second cage 212b may be mounted in a belly-to-belly configuration such that the bottom side of the first cage 212a and the bottom side of the second cage 212b are both mounted to the cold plate 104. As illustrated, the third cage 212c and the fourth cage 212d are also provided in a belly-to-belly configuration. The belly-to-belly configuration may support an efficient use of space and accommodate a greater number of cages than if a different configuration were used. Each of cages 212a, 212b, 212c, 212d may be attached to the cold plate 104 with one or more fasteners. For instance, a number of screws may be used to attach each cage 212a, 212b, 212c, 212d to the cold plate 104, significantly simplifying the assembly process and reducing precision requirements.

While each cage 212a, 212b, 212c, 212d is illustrated to include six receptacles 108, it should be appreciated that a cage does not necessarily need to include six receptacles 108. In particular, a cage 212 may be provided with a greater or lesser number of receptacles 108 without departing from the scope of the present disclosure. A cage 212 may include one, two, three, four, or more receptacles in accordance with embodiments of the present disclosure.

The cold plate 104 is also shown to include a PCB 204 embedded therein. In some embodiments, the PCB 204 may include one or more features that enable the PCB 204 to be press-fit into a recess of the cold plate 104. In addition to supporting a press-fit connection between the PCB 204 and cold plate 104, one or more screws may also be used to secure the PCB 204 with the cold plate 104 after the PCB 204 has been pressed into a desired location of the cold plate 104. In some embodiments, the cold plate 104 is manufactured with a different tolerance than the PCB 204. For instance, the PCB 204 may be manufactured with a tighter or stricter tolerance whereas the cold plate 104 is manufactured with a looser or more relaxed tolerance. The utilization of a press-fit solution helps to avoid the need to match manufacturing tolerances between the cold plate 104 and PCB 204.

As can be appreciated, the PCB 204 may be used to carry signals between the receptacles 108 when pluggable transceiver modules 120 are connected thereto. For instance, the PCB 204 may support electrical switching operations or other functions between the various ports represented by the receptacles 108 in the cages 212a, 212b, 212c, 212d.

As can be appreciated, the cages may be provided toward the front surface 124 of the cold plate 104. In some embodiments, providing the cages toward the front surface 124 of the cold plate 104 enables the receptacles 108 of the cages 212a, 212b, 212c, 212d to be exposed or accessible at a front panel of the system 100. In this way, the cages 212a, 212b, 212c, 212d are relatively easy to access when the cold plate 104 is installed in a larger rack, which makes connecting the pluggable transceiver module 120 thereto an easier task.

A PCB is used to electrically connect electronic components using conductive pathways, or traces, etched from metal sheets. In many electronic systems, one or more very large-scale integrated circuit (“VLSI”) components is coupled to a host system PCB. Such VLSI components may include, for example, CPU devices and GPU devices. The PCB may hold at least one processing circuitry. The processing circuitry may comprise hardware, such as an application specific integrated circuit (ASIC). The processing circuitry may comprise an ASIC and/or may be capable of performing as a CPU, a GPU, a network interface card (NIC), a data processing unit (DPU), or any other computing device in which with data is received and/or transmitted. Other non-limiting examples of the processing circuitry include an Integrated Circuit (IC) chip, a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the processing circuitry. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, that is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

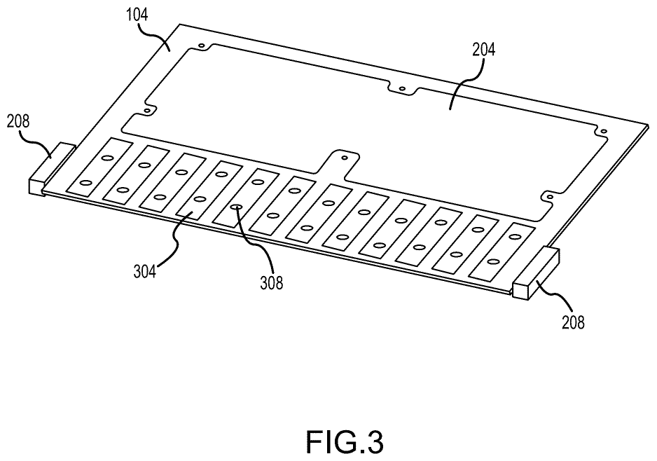

Referring now to FIG. 3, a view of the cold plate 104 is provided with the cages 212a, 212b, 212c, 212d hidden from view. As can be seen, the cold plate 104 may include a plurality of holes 308 on the top surface thereof. While not shown in FIG. 3, it should be appreciated that a similar set of holes are provided on the bottom surface of the cold plate 104 to support the attachment of the cages 212a, 212b, 212c, 212d to the cold plate 104. In some embodiments, each hole 308 may be configured to receive and fastener, such as a screw, that fastens the cages 212a, 212b, 212c, 212d to the top or bottom surface of the cold plate 104. If the event that the fastener includes a screw, the holes 308 may comprise internal threading to mate with the external threading of a screw.

FIG. 3 also illustrates the use of one or more strips of a TIM 304. The TIM 304 may be provided between the cages 212a, 212b, 212c, 212d and the cold plate 104. In some embodiments, the TIM 304 may include at least one of a grease, elastomeric pad, tape, film, phase change material, gel, adhesive, and paste. The TIM 304 may enhance the thermal transfer between the cages 212a, 212b, 212c, 212d and the cold plate 104.

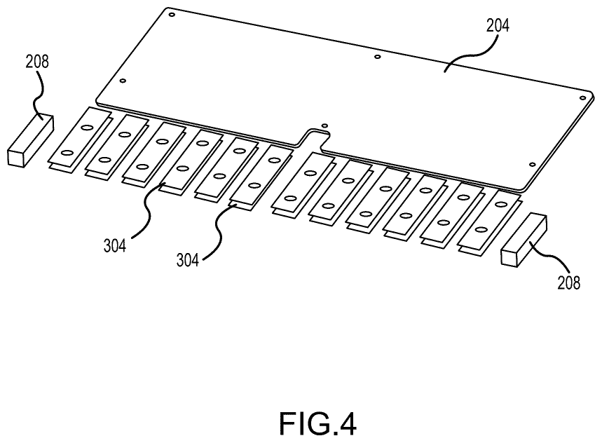

FIG. 4 illustrates the components shown in FIG. 3 with the exception of the cold plate 104. As can be seen in FIG. 4, strips of a TIM 304 may be provided on a top surface of the cold plate 104 and a bottom surface of the cold plate 104. More specifically, a strip of a TIM 304 may be provided for each cage in the cages 212a, 212b, 212c, 212d.

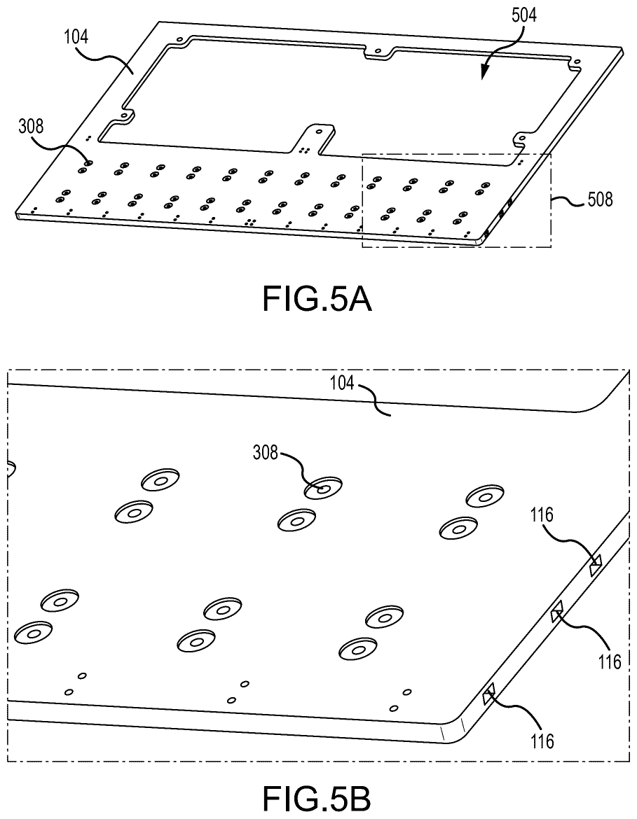

With reference now to FIGS. 5A and 5B, additional details of a cold plate 104 will be described in accordance with at least some embodiments of the present disclosure. FIG. 5B provides a detailed view within window 508.

The cold plate 104 is shown to include a recess 504 in addition to the plurality of holes 308. Again, the plurality of holes 308 may support connections with the cages 212a, 212b, 212c, 212d. The plurality of holes 308 may or may not pass entirely through the cold plate 104. In other words, the holes 308 may have a depth that is less than a thickness of the cold plate 104. In other embodiments, the holes 308 may extend entirely through the cold plate 104.

FIGS. 5A and 5B further illustrate how the holes 308 may be offset relative to the conduit(s) 116. Specifically, because the one or more conduits 116 may traverse the entire width of the cold plate 104, the holes 308 are provided in locations of the cold plate 104 offset away from the one or more conduits 116. Placing the holes 308 in such a position relative to the one or more conduits ensures that the one or more conduits 116 are not interrupted by any holes 308 and further ensures that no fastener or screw obstructs the one or more conduits 116.

It is also noted that the surface of the cold plate 104 surrounding each hole 308 may include a relief that is configured to accept a corresponding protrusion on a bottom of a cage. The use of a relief and corresponding protrusion can help decrease the overall profile associated with the system 100.

While the holes 308 support attachment of the cages 212a, 212b, 212c, 212d thereto, the recess 504 may receive the PCB 204. In some embodiments, a first tolerance is used to construct the cold plate 104 and specifically the recess 504 in the cold plate 104 whereas a second tolerance may or may not be used to construct the PCB 204. In other words, the construction and features of the PCB 204 and recess 504 may support the use of different tolerances, thereby improving the manufacturability and assembly associated with the system 100.

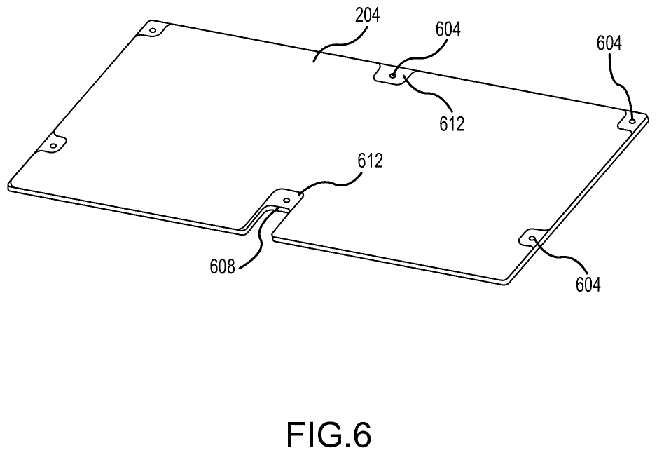

As can be seen in FIG. 6, the PCB 204 may include a plurality of holes 604 to receive a screw or fastener that connects the PCB 204 to the cold plate 104. Each hole 604 may be provided in one or more surrounding reliefs 612. The surrounding reliefs 612 may support a press-fit mating with the cold plate 104 in addition to helping lower a profile of the fastener used to secure the PCB 204 to the cold plate 104 through the holes 604.

In addition to the surrounding reliefs 612, the PCB 204 may also include one or more notches 608. The one or more notches 608 may help fix a position of the PCB 204 relative to the cold plate 104. For instance, the notch 608 illustrated in FIG. 6 may help to support a fixation of the PCB 204 in the same plane as the cold plate 104 (e.g., in an x and y plane). While the PCB 204 is shown to have a single notch 608 and the cold plate 104 is shown to have a corresponding feature to mate with the notch 608, it should be appreciated that the PCB 204 may be provided with more than one notch 608 and the cold plate 104 can be provided with a corresponding number of mating features.

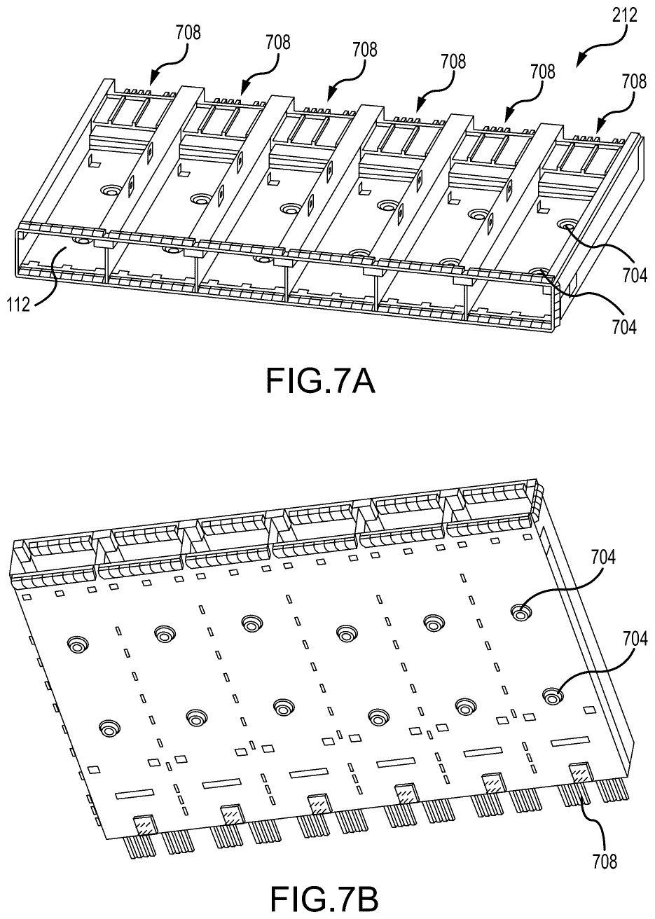

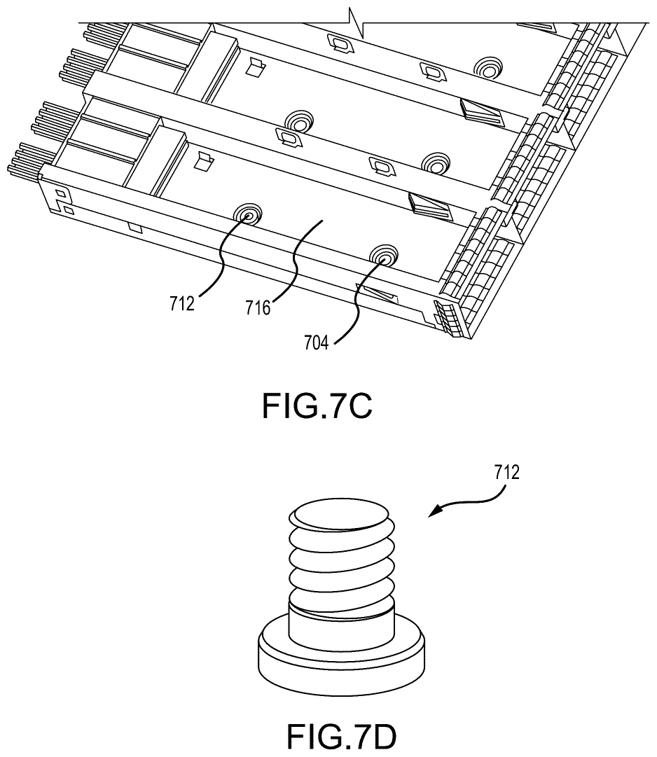

Referring now to FIGS. 7A, 7B, 7C, and 7D, additional details of cages 212 and the components thereof will be described in accordance with at least some embodiments of the present disclosure. The cage 212, as shown above in connection with FIG. 2, may be mounted to a top surface or bottom surface of the cold plate 104. In some embodiments, a bottom surface 716 of the cage 212 (e.g., the closed side of the cage 212) may be mounted directly to a surface of the cold plate 104 using one or more fasteners 712. A fastener 712 may pass through a corresponding hole 704 provided in a bottom surface of the cage 212 and then couple with a corresponding hole 308 in the cold plate 104. The fastener 712 may correspond to a screw, bolt, pin, or the like.

In some embodiments, each cage 212 may include a number of receptacles 108 (e.g., one, two, three, four, . . . , ten, or more), with each receptacle 108 being configured to receive an pluggable transceiver module 120. Each receptacle 108 may also have one or more corresponding holes 704 provided therein. As noted above, holes 704 of the cage 212 may align with holes 308 in the cold plate 104, which are offset from the one or more conduits 116 passing through the cold plate 104. The holes 704 may also be provided with a surrounding detent, which helps lower the profile of the fastener 712 within the cage 212. More specifically, a surrounding detent may be provided with a depth that is greater than or equal to a thickness of a head of the fastener 712. In this way, the fastener 712 can secure the cage 212 to the cold plate 104 and the head of the fastener 712 can be substantially flush or below the bottom surface 716 of the cage 212. Positioning the fastener 712 below a bottom surface 716 of the cage 212 can help to ensure that the fastener 712 does not interfere with an insertion of the pluggable transceiver module 120 into the receptacle opening 112.

A fully-inserted pluggable transceiver module 120 may be configured to exchange electrical signals with the PCB 204 via electrical interconnects 708. Each receptacle 108 may be provided with a corresponding set of interconnects 708 that are used to carry electrical signals between the pluggable transceiver module 120 inserted in the receptacle opening 112 and the PCB 204. The electrical interconnects 708 may include one or more of wires, traces, electrical contacts, conductive bumps, and the like.

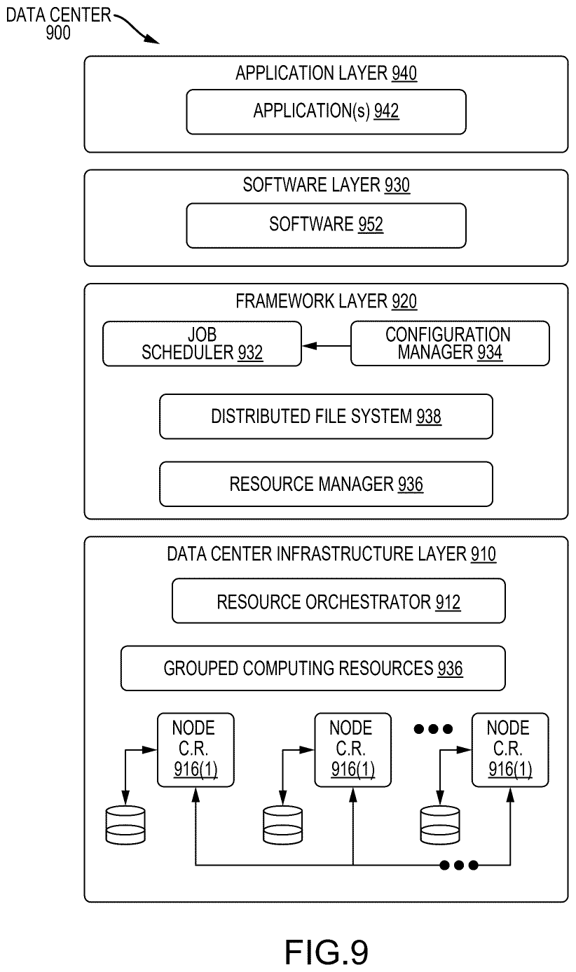

FIG. 9 illustrates additional components of an example data center 900 according to at least some embodiments of the present disclosure. The data center 900 may also include one or more modules subject to one or more cooling/thermal management features as described herein.

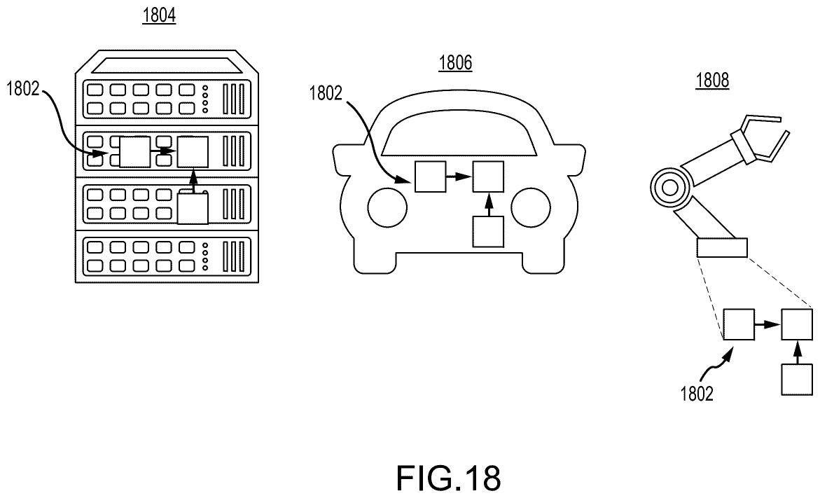

In at least one embodiment, data center 900 includes a data center infrastructure layer 910, a framework layer 920, a software layer 930, and an application layer 930. In at least one embodiment, the infrastructure layer 910, the framework layer 920, the software layer 930, and the application layer 940 may be partly or fully provided via computing components on server trays located in racks of a data center, such as data center 1802 depicted and described in FIG. 18A-18C. This enables cooling systems of the present disclosure to direct cooling to certain ones of the computing features and the interconnect features, in an efficient and effective manner. Further, aspects of the data center 1802, including the data center infrastructure layer 910, the framework layer 920, the software layer 930, and the application layer 940 may be used to support selection or design of the intermediate layers. As such, the discussion in reference to FIG. 9 may be understood to apply to the hardware and software features required to enable or support cooling functionality, for instance.

In at least one embodiment, as in FIG. 9, data center infrastructure layer 910 may include a resource orchestrator 912, grouped computing resources 936, and node computing resources (“node C.R. s”) 916(1)-916(N), where “N” represents any whole, positive integer. In at least one embodiment, node C.R.s 916(1)-916(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 916(1)-916(N) may be a server having one or more of above-mentioned computing resources.

In at least one embodiment, grouped computing resources 936 may include separate groupings of node C.R.s housed within one or more racks (not shown), or many racks housed in data centers at various geographical locations (also not shown). Separate groupings of node C.R.s within grouped computing resources 936 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 912 may configure or otherwise control one or more node C.R.s 916(1)-916(N) and/or grouped computing resources 936. In at least one embodiment, resource orchestrator 912 may include a software design infrastructure (“SDI”) management entity for data center 900. In at least one embodiment, resource orchestrator may include hardware, software or some combination thereof.

In at least one embodiment, as shown in FIG. 9, framework layer 920 includes a job scheduler 932, a configuration manager 934, a resource manager 936 and a distributed file system 938. In at least one embodiment, framework layer 920 may include a framework to support software 952 of software layer 930 and/or one or more application(s) 942 of application layer 940. In at least one embodiment, software 952 or application(s) 942 may respectively include web-based service software or applications, such as those provided by Amazon Web Services, Google Cloud and Microsoft Azure. In at least one embodiment, framework layer 920 may be, but is not limited to, a type of free and open-source software web application framework such as Apache Spark^{TM} (hereinafter “Spark”) that may utilize distributed file system 938 for large-scale data processing (such as “big data”). In at least one embodiment, job scheduler 932 may include a Spark driver to facilitate scheduling of workloads supported by various layers of data center 900. In at least one embodiment, configuration manager 934 may be capable of configuring different layers such as software layer 930 and framework layer 920 including Spark and distributed file system 938 for supporting large-scale data processing. In at least one embodiment, resource manager 936 may be capable of managing clustered or grouped computing resources mapped to or allocated for support of distributed file system 938 and job scheduler 932. In at least one embodiment, clustered or grouped computing resources may include grouped computing resource 936 at data center infrastructure layer 910. In at least one embodiment, resource manager 936 may coordinate with resource orchestrator 912 to manage these mapped or allocated computing resources.

In at least one embodiment, software 952 included in software layer 930 may include software used by at least portions of node C.R.s 916(1)-916(N), grouped computing resources 936, and/or distributed file system 938 of framework layer 920. One or more types of software may include, but are not limited to, Internet web page search software, e-mail virus scan software, database software, and streaming video content software.

In at least one embodiment, application(s) 942 included in application layer 940 may include one or more types of applications used by at least portions of node C.R.s 916(1)-916(N), grouped computing resources 936, and/or distributed file system 938 of framework layer 920. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 934, resource manager 936, and resource orchestrator 912 may implement any number and type of self-modifying actions based on any amount and type of data acquired in any technically feasible fashion. In at least one embodiment, self-modifying actions may relieve a data center operator of data center 900 from making possibly bad configuration decisions and possibly avoiding underutilized and/or poor performing portions of a data center.

In at least one embodiment, data center 900 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to data center 900. In at least one embodiment, trained machine learning models corresponding to one or more neural networks may be used to infer or predict information using resources described above with respect to data center 900 by using weight parameters calculated through one or more training techniques. Deep learning may be advanced using any appropriate learning network and the computing capabilities of the data center 900. As such, a deep neural network (DNN), a recurrent neural network (RNN) or a convolutional neural network (CNN) may be supported either simultaneously or concurrently using the hardware in the data center. Once a network is trained and successfully evaluated to recognize data within a subset or a slice, for instance, the trained network can provide similar representative data for using with the collected data.

In at least one embodiment, data center 900 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as pressure, flow rates, temperature, and location information, or other artificial intelligence services.

Inference and/or training logic may be used to perform inferencing and/or training operations associated with one or more embodiments. In at least one embodiment, inference and/or training logic may be used in system FIG. 9 for inferencing or predicting operations based, at least in part, on weight parameters calculated using neural network training operations, neural network functions and/or architectures, or neural network use cases described herein. In at least one embodiment, inference and/or training logic may include, without limitation, hardware logic in which computational resources are dedicated or otherwise exclusively used in conjunction with weight values or other information corresponding to one or more layers of neurons within a neural network. In at least one embodiment, inference and/or training logic may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic may be used in conjunction with central processing unit (CPU) hardware, graphics processing unit (GPU) hardware or other hardware, such as field programmable gate arrays (FPGAs). In at least one embodiment, inference and/or training logic includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic.

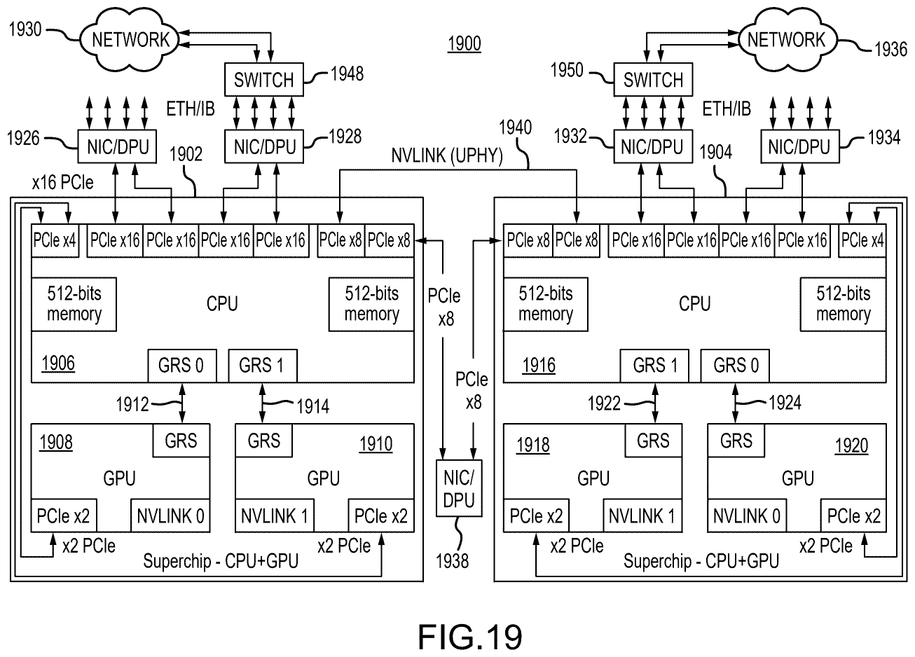

As shown in FIGS. 19A and/or 19B, various network topologies may be deployed within the data center 1900. For instance, and without limitation, the switches within each layer (e.g., edge layer, aggregation layer, core layer) may be 1U switches. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

The terms “electrical switch,” “electrical switching ASIC,” “ASIC,” and variants thereof may used interchangeably. Although some figures illustrated herein show the electrical switches in the electrical blocks as being embodied by ASICs, example embodiments are not limited thereto, and the electrical switches may be implemented with any suitable hardware and/or software that enables routing of signals in the electrical domain. In addition, a set of optical switches at one or more levels of a hybrid optoelectrical switch may be referred to herein as an optical block while a set of electrical switches at one or more levels of a hybrid optoelectrical switch may be referred to as an electrical block.

For example, an electrical switch may include receivers that receive and convert optical signals into electrical signals for routing within the electrical switch. For example, a receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In at least one example embodiment, receiver/transmitter pairs are integrated into a single transceiver. Each electrical switch may further include internal switching circuitry for routing electrical signals within the electrical switch.

Embodiments of the present disclosure are not just limited to electrical and/or optoelectronic switches. It should be appreciated that embodiments of the present disclosure may also be utilized in quantum switches or in data centers 1900 comprising one or more quantum switches.

Data security and privacy are among the top concerns in the data center environment. The financial cost of a security breach can be substantial, especially when customer data is exposed. Sensitive data has historically been protected by Internet Protocol (IP) segmentation and firewalls with intrusion prevention systems that were simple and faster than encryption. However, as workloads in the corporate data enter begin to migrate to the public cloud, the need to encrypt any data traversing the network becomes foundational. Hyperscale cloud service providers are increasingly enabling encryption across their massive Data Center Interconnect (DCI) networks to meet customer expectations.

To eliminate vulnerabilities in the public cloud infrastructure all segments of the cloud data center network need to be fortified with encryption, including the intra-data center segment which poses additional challenges due to the large number of connections and smaller margins.

Overall, the security of an encryption system is limited by its weakest link. In existing systems, the known weakest link is identified as the key exchange protocol like Diffie-Hellman and Rivest-Shamir-Adleman (RSA). These systems rely on the computational complexity of the associated algorithms; it is in principle possible to hack the system provided that extremely strong processing power is available. Current systems are designed in such a way that breaking the key exchange algorithm would take unrealistic time even if the state-of-the-art processing systems are used, thus making the encryption practically unhackable. However, the advent of quantum computers is expected to disrupt this methodology since the available processing power will scale exponentially.

A quantum computer capable of implementing Shor's algorithm could factor large integers exponentially faster than a classical computer, rendering common asymmetric public key encryption protocols such as RSA ineffective. Such a quantum computer can crack public encryption protocols much faster than a classical computer, rendering them unsecure. New “quantum secure” key exchange solutions are required, and ongoing research is investigating software and hardware approaches. On the software side, Post Quantum Cryptography (PQC) is focusing on algorithms that are quantum-resistant (e.g., encryption methods based on math that a quantum computer is not advantaged in computing). On the hardware side, Quantum Key Distribution (QKD) facilitates key exchange by exchanging photons which, by the principles of quantum physics, will be perturbed in a detectable way if an eavesdropper is present. Consensus is that for highest security a hybrid approach should be pursued, combining PQC with QKD.

A pervasive and future-proof solution for intra-data center security combining PQC and QKD faces several challenges, primarily related to the hardware nature and current implementation particularities of QKD.

QKD equipment is commercially available and is finding application in use cases where particular point-to-point links need to be secured, such as in inter-data center connections. The hardware essence of QKD requires changes to the overall network design and infrastructure. Typically, QKD equipment is added alongside existing network equipment to facilitate key exchange in select connections which are considered non-trusted. For example, in the DCI use case, each individual data center network is considered a trusted zone and only the connections between data centers are enhanced by QKD. Hence, only the DCI-facing ports of the relevant network infrastructure are combined with the QKD equipment and are encrypted using QKD keys. Current QKD equipment is considerably bulky (e.g., a rack mountable form factor with several rack units of height); however, as only a few units are needed, integration is feasible without significant implications to the data center operator. However, when migrating to an intra-data center installation following the zero-trust concept where all links have to be secured, the number of QKD connections rises dramatically. The current form factor of QKD equipment inhibits realistic deployment inside the data center as it would consume the majority of each rack's volume and would degrade computational density. It is expected that new technologies (such as photonic integrated circuits) will enable the future miniaturization of QKD equipment.

A switch, whether electric, optoelectronic, and/or quantum, may include input circuit(s) and output circuit(s), linked by switching core. In some embodiments, a switch may include multiple inputs and outputs.

A number of architectures of this type have been proposed, including “Next Generation I/O” (NGIO) and “Future I/O” (FIO), culminating in the “InfiniBand” architecture, which has been advanced by a consortium led by a group of industry leaders (including Intel, Sun, Hewlett Packard, IBM, Compaq, Dell and Microsoft). Storage Area Networks (SAN) provide a similar, packetized, serial approach to high-speed storage access, which can also be implemented using an InfiniBand fabric.

Communications between a parallel bus and a packet network generally require a communications interface, to convert bus cycles into appropriate packets and vice versa. For example, a host channel adapter or target channel adapter can be used to link a parallel bus, such as the PCI bus, to the InfiniBand fabric. When the adapter receives data from a device on the PCI bus, it inserts the data in the payload of an InfiniBand packet, and then adds an appropriate header and error checking code, such as a cyclic redundancy check (CRC) code, as required for network transmission. The InfiniBand packet header includes a routing header and a transport header. The routing header contains information at the data link protocol level, including fields required for routing the packet within and between fabric subnets. The transport header contains higher-level, end-to-end transport protocol information. Similar headers are used in other types of packet networks known in the art, such as Internet Protocol (IP) networks.

In at least one embodiment, aspects of the present disclosure may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, a computer system having one or more aspects of the present disclosure may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

The following figures set forth, without limitation, example computer-based systems that can be used to implement at least one embodiment.

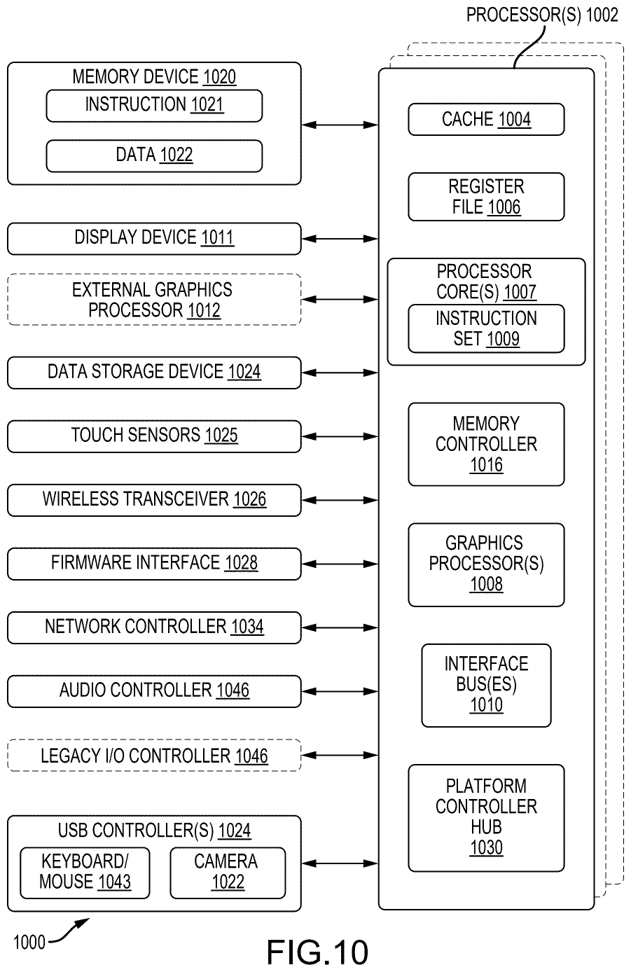

FIG. 10 illustrates a processing system 1000 that may benefit from or include one or more cooling components as depicted and described herein. In at least one embodiment, processing system 1000 includes one or more processors 1002 and one or more graphics processors 1008, and may be a single processor desktop system, a multiprocessor workstation system, or a server system having a large number of processors 1002 or processor cores 1007. In at least one embodiment, processing system 1000 is a processing platform incorporated within a system-on-a-chip (“Sort”) integrated circuit for use in mobile, handheld, or embedded devices.

In at least one embodiment, processing system 1000 can include, or be incorporated within a server-based gaming platform, a game console, a media console, a mobile gaming console, a handheld game console, or an online game console. In at least one embodiment, processing system 1000 is a mobile phone, smart phone, tablet computing device or mobile Internet device. In at least one embodiment, processing system 1000 can also include, couple with, or be integrated within a wearable device, such as a smart watch wearable device, eyewear device, augmented reality device, or virtual reality device. In at least one embodiment, processing system 1000 is a television or set top box device having one or more processors 1002 and a graphical interface generated by one or more graphics processors 1008.

In at least one embodiment, one or more processors 1002 each including one or more processor cores 1007 to process instructions which, when executed, perform operations for system and user software. In at least one embodiment, each of one or more processor cores 1007 is configured to process a specific instruction set 1009. In at least one embodiment, instruction set 1009 may facilitate Complex Instruction Set Computing (“CISC”), Reduced Instruction Set Computing (“RISC”), or computing via a Very Long Instruction Word (“VLIW”). In at least one embodiment, processor cores 1007 may each process a different instruction set 1009, which may include instructions to facilitate emulation of other instruction sets. In at least one embodiment, processor core 1007 may also include other processing devices, such as a digital signal processor (“DSP”).

In at least one embodiment, processor 1002 includes cache memory (“cache”) 1004. In at least one embodiment, processor 1002 can have a single internal cache or multiple levels of internal cache. In at least one embodiment, cache memory is shared among various components of processor 1002. In at least one embodiment, processor 1002 also uses an external cache (e.g., a Level 3 (“L3”) cache or Last Level Cache (“LLC”)) (not shown), which may be shared among processor cores 1007 using known cache coherency techniques. In at least one embodiment, register file 1006 is additionally included in processor 1002 which may include different types of registers for storing different types of data (e.g., integer registers, floating point registers, status registers, and an instruction pointer register). In at least one embodiment, register file 1006 may include general-purpose registers or other registers.

In at least one embodiment, one or more processor(s) 1002 are coupled with one or more interface bus(es) 1010 to transmit communication signals such as address, data, or control signals between processor 1002 and other components in processing system 1000. In at least one embodiment interface bus 1010, in one embodiment, can be a processor bus, such as a version of a Direct Media Interface (“DMI”) bus. In at least one embodiment, interface bus 1010 is not limited to a DMI bus and may include one or more Peripheral Component Interconnect buses (e.g., “PCI,” PCI Express (“PCIe”)), memory buses, or other types of interface buses. In at least one embodiment processor(s) 1002 include an integrated memory controller 1016 and a platform controller hub 1030. In at least one embodiment, memory controller 1016 facilitates communication between a memory device and other components of processing system 1000, while platform controller hub (“PCH”) 1030 provides connections to Input/Output (“I/O”) devices via a local I/O bus. Connections between components of system 1000 may benefit from one or more cooling mechanisms depicted and described herein.

In at least one embodiment, memory device 1020 can be a dynamic random-access memory (“DRAM”) device, a static random-access memory (“SRAM”) device, flash memory device, phase-change memory device, or some other memory device having suitable performance to serve as processor memory. In at least one embodiment memory device 1020 can operate as system memory for processing system 1000, to store data 1022 and instructions 1021 for use when one or more processors 1002 executes an application or process. In at least one embodiment, memory controller 1016 also couples with an optional external graphics processor 1012, which may communicate with one or more graphics processors 1008 in processors 1002 to perform graphics and media operations. In at least one embodiment, a display device 1011 can connect to processor(s) 1002. In at least one embodiment display device 1011 can include one or more of an internal display device, as in a mobile electronic device or a laptop device or an external display device attached via a display interface (e.g., DisplayPort, etc.). In at least one embodiment, display device 1011 can include a head mounted display (“HMD”) such as a stereoscopic display device for use in virtual reality (“VR”) applications or augmented reality (“AR”) applications.

In at least one embodiment, platform controller hub 1030 enables peripherals to connect to memory device 1020 and processor 1002 via a high-speed I/O bus. In at least one embodiment, I/O peripherals include, but are not limited to, an audio controller 1046, a network controller 1034, a firmware interface 1028, a wireless transceiver 1026, touch sensors 1025, a data storage device 1024 (e.g., hard disk drive, flash memory, etc.). In at least one embodiment, data storage device 1024 can connect via a storage interface (e.g., SATA) or via a peripheral bus, such as PCI, or PCIe. In at least one embodiment, touch sensors 1025 can include touch screen sensors, pressure sensors, or fingerprint sensors. In at least one embodiment, wireless transceiver 1026 can be a Wi-Fi transceiver, a Bluetooth transceiver, or a mobile network transceiver such as a 3G, 4G, or Long Term Evolution (“LTE”) transceiver. In at least one embodiment, firmware interface 1028 enables communication with system firmware, and can be, for example, a unified extensible firmware interface (“UEFI”). In at least one embodiment, network controller 1034 can enable a network connection to a wired network. In at least one embodiment, a high-performance network controller (not shown) couples with interface bus 1010. In at least one embodiment, audio controller 1046 is a multi-channel high definition audio controller. In at least one embodiment, processing system 1000 includes an optional legacy I/O controller 1046 for coupling legacy (e.g., Personal System 2 (“PS/2”)) devices to processing system 1000. In at least one embodiment, platform controller hub 1030 can also connect to one or more Universal Serial Bus (“USB”) controllers 1025 connect input devices, such as keyboard and mouse 1043 combinations, a camera 1022, or other USB input devices.

In at least one embodiment, an instance of memory controller 1016 and platform controller hub 1030 may be integrated into a discreet external graphics processor, such as external graphics processor 1012. In at least one embodiment, platform controller hub 1030 and/or memory controller 1016 may be external to one or more processor(s) 1002. For example, in at least one embodiment, processing system 1000 can include an external memory controller 1016 and platform controller hub 1030, which may be configured as a memory controller hub and peripheral controller hub within a system chipset that is in communication with processor(s) 1002.

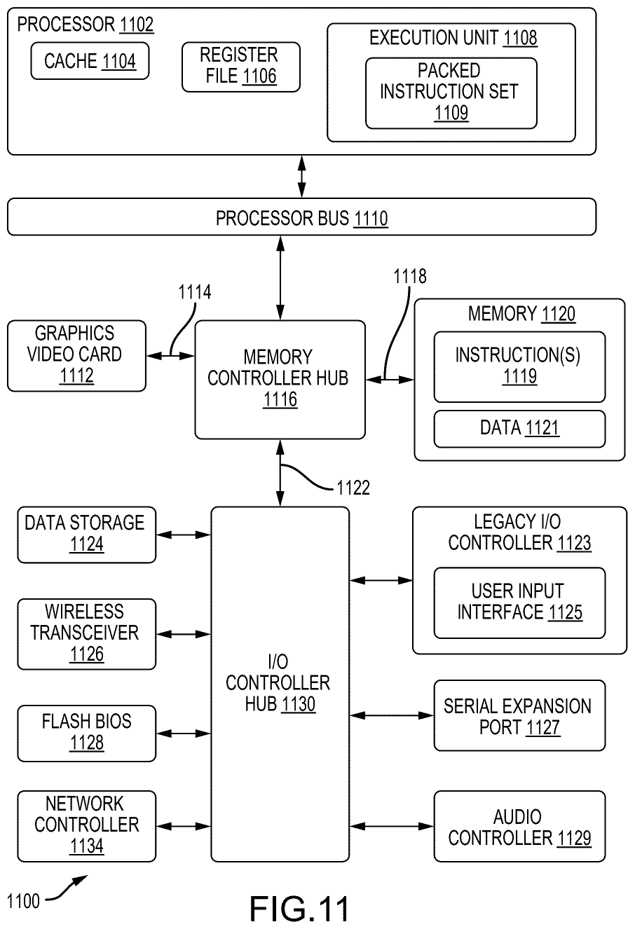

FIG. 11 illustrates a computer system 1100 that can include one or more cooling mechanisms depicted and described herein. In at least one embodiment, computer system 1100 may be a system with interconnected devices and components, an SOC, or some combination. Interconnections between such devices and components may include one or more receptacles 108 and/or pluggable transceiver modules 120. In at least one embodiment, computer system 1100 is formed with a processor 1102 that may include execution units to execute an instruction. In at least one embodiment, computer system 1100 may include, without limitation, a component, such as processor 1102 to employ execution units including logic to perform algorithms for processing data. In at least one embodiment, computer system 1100 may include processors, such as PENTIUM® Processor family, Xeon™, Itanium®, XScale™ and/or StrongArm™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1100 may execute a version of WINDOWS' operating system available from Microsoft Corporation of Redmond, Wash., although other operating systems (UNIX and Linux for example), embedded software, and/or graphical user interfaces, may also be used.

In at least one embodiment, computer system 1100 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“Net PCs”), set-top boxes, network hubs, wide area network (“WAN”) switches, or any other system that may perform one or more instructions.

In at least one embodiment, computer system 1100 may include, without limitation, processor 1102 that may include, without limitation, one or more execution units 1108 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 1100 is a single processor desktop or server system. In at least one embodiment, computer system 1100 may be a multiprocessor system. In at least one embodiment, processor 1102 may include, without limitation, a CISC microprocessor, a RISC microprocessor, a VLIW microprocessor, a processor implementing a combination of instruction sets, or any other processor device, such as a digital signal processor, for example. In at least one embodiment, processor 1102 may be coupled to a processor bus 1110 that may transmit data signals between processor 1102 and other components in computer system 1100.

In at least one embodiment, processor 1102 may include, without limitation, a Level 1 (“L1”) internal cache memory (“cache”) 1104. In at least one embodiment, processor 1102 may have a single internal cache or multiple levels of internal cache. In at least one embodiment, cache memory may reside external to processor 1102. In at least one embodiment, processor 1102 may also include a combination of both internal and external caches. In at least one embodiment, a register file 1106 may store different types of data in various registers including, without limitation, integer registers, floating point registers, status registers, and instruction pointer register.

In at least one embodiment, execution unit 1108, including, without limitation, logic to perform integer and floating-point operations, also resides in processor 1102. Processor 1102 may also include a microcode (“ucode”) read only memory (“ROM”) that stores microcode for certain macro instructions. In at least one embodiment, execution unit 1108 may include logic to handle a packed instruction set 1109. In at least one embodiment, by including packed instruction set 1109 in an instruction set of a general-purpose processor 1102, along with associated circuitry to execute instructions, operations used by many multimedia applications may be performed using packed data in a general-purpose processor 1102. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 1108 may also be used in microcontrollers, embedded processors, graphics devices, DSPs, and other types of logic circuits. In at least one embodiment, computer system 1100 may include, without limitation, a memory 1120. In at least one embodiment, memory 1120 may be implemented as a DRAM device, an SRAM device, flash memory device, or other memory device. Memory 1120 may store instruction(s) 1119 and/or data 1121 represented by data signals that may be executed by processor 1102.

In at least one embodiment, a system logic chip may be coupled to processor bus 1110 and memory 1120. In at least one embodiment, the system logic chip may include, without limitation, a memory controller hub (“MCH”) 1116, and processor 1102 may communicate with MCH 1116 via processor bus 1110. In at least one embodiment, MCH 1116 may provide a high bandwidth memory path 1118 to memory 1120 for instruction and data storage and for storage of graphics commands, data, and textures. In at least one embodiment, MCH 1116 may direct data signals between processor 1102, memory 1120, and other components in computer system 1100 and to bridge data signals between processor bus 1110, memory 1120, and a system I/O 1122. In at least one embodiment, system logic chip may provide a graphics port for coupling to a graphics controller. In at least one embodiment, MCH 1116 may be coupled to memory 1120 through high bandwidth memory path 1118 and graphics/video card 1112 may be coupled to MCH 1116 through an Accelerated Graphics Port (“AGP”) interconnect 1114.

In at least one embodiment, computer system 1100 may use system I/O 1122 that is a proprietary hub interface bus to couple MCH 1116 to I/O controller hub (“ICH”) 1130. In at least one embodiment, ICH 1130 may provide direct connections to some I/O devices via a local I/O bus. In at least one embodiment, local I/O bus may include, without limitation, a high-speed I/O bus for connecting peripherals to memory 1120, a chipset, and processor 1102. Examples may include, without limitation, an audio controller 1129, a firmware hub (“flash BIOS”) 1128, a wireless transceiver 1126, a data storage 1124, a legacy I/O controller 1123 containing a user input interface 1125 and a keyboard interface, a serial expansion port 1127, such as a USB, and a network controller 1134. Data storage 1124 may comprise a hard disk drive, a floppy disk drive, a CD-ROM device, a flash memory device, or other mass storage device.

In at least one embodiment, FIG. 11 illustrates a system, which includes interconnected hardware devices or “chips.” In at least one embodiment, FIG. 11 may illustrate an example SoC. In at least one embodiment, devices illustrated in FIG. 11 may be interconnected with proprietary interconnects, standardized interconnects (e.g., PCIe), or some combination thereof. In at least one embodiment, one or more components of system 1100 are interconnected using compute express link (“CXL”) interconnects.

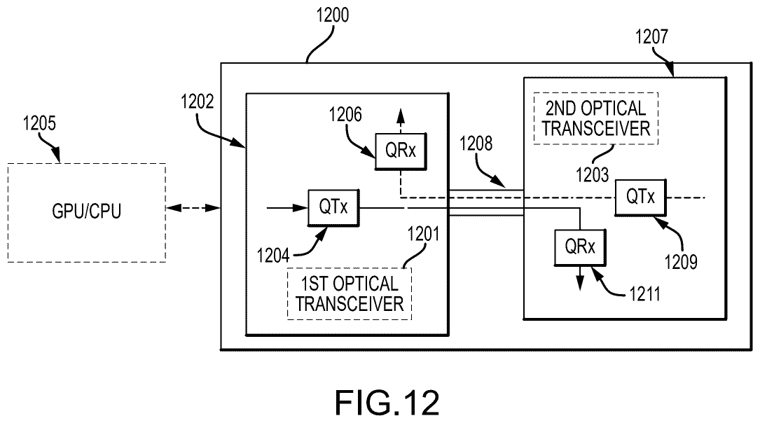

With reference to FIG. 12, an example bi-directional quantum interconnect 1200 (e.g., interconnect 1200) is illustrated. The interconnect 1200 may include one or more elements of system 100, such as a receptacle 108 and/or an pluggable transceiver module 120. As shown, the interconnect 1200 may include a first communication module 1202 and a second communication module 1207 communicably coupled by a first communication medium 1208. The first communication module 1202 may include a first quantum transmitter 1204 configured to generate quantum particles (e.g., qubit) for transmission. A photon refers to a fundamental unit of electromagnetic radiation and, in quantum communication systems, may serve as the object within which data is encoded. The quantum basis of the qubits refers to the way in which data is encoded and/or the quantum information is carried, by the first quantum transmitter 1204, where the data is the value of the encoded information. This encoding may be accomplished via sets of orthogonal quantum states, including, but not limited to, pairs of photonic polarization states, phase of single photons, time of arrival, optical frequency, quadratures, etc. The pairs of photonic polarization states may include, for example, the rectilinear, diagonal, and circular photonic polarization states. The rectilinear basis may refer to the pair of rectilinear photonic polarization states including the horizontal photon polarization state |0>and the vertical photon polarization state |1>. The diagonal basis may refer to the pair of diagonal and anti-diagonal photonic polarization states at 45 and 135 degrees, respectively. The circular basis may refer to the pair of circular photonic polarization states include the left circular photon polarization state IL) and the right circular photon polarization state |R>. The terms “state” or “states” may refer to a basic unit of quantum information comprising a two-level quantum mechanical system, such as the polarization of a single photon (e.g., a photon encoded using a quantum basis as described above).

Although described herein with reference to qubits transmitted via a quantum communication channel, the present disclosure contemplates that the techniques described herein may be applicable to quantum particles of any type. Furthermore, the basis (e.g., quantum state) of the qubit(s) transmitted by the first quantum transmitter 1204 may be only one such example of a first quantum characteristic of the qubits transmitted by the first quantum transmitter 1204. By way of a non-limiting example, the frequency, wavelength, and/or any other quantum characteristic, property, attribute, etc. of the qubits generated and transmitted by the first quantum transmitter 1204 may be varied based upon the intended application of the first communication module 1202. As described more fully hereinafter, the first quantum characteristics associated with the qubit(s) generated and transmitted by the first communication transmitter 1204 may be at least partially impacted by the quantum characteristics associated with other qubits transmitted within the same communication medium (e.g., quantum communication channel via an optical fiber or free space). Still further, the first quantum characteristics associated with the qubit(s) generated and transmitted by the first communication module 1202 may be, in some embodiments, at least partially impacted or controlled by the equipment capabilities associated with the first quantum transmitter 1204.

The first communication module 1202 may further include a first quantum receiver 1206 configured to receive (e.g., measure) qubits. As described hereafter, the first quantum receiver 1206 may be configured to measure qubits that are received, via the first communication medium 1208, from the second communication module 1207 (e.g., generated by a second quantum transmitter 1209). By way of continued example, the qubit serves as the object in quantum communication within which data is encoded, and the quantum basis of the qubit refers to a way in which data is encoded. As such, the first quantum receiver 1206 may be configured to measure qubits having second quantum characteristics, such as a quantum basis state used to encode data, the frequency of the qubits, the wavelength of the qubits, and/or the like. As described hereafter, at least one of the second quantum characteristics may be different from at least one of the first quantum characteristics so that qubits having the first quantum characteristics (e.g., transmitted by the first quantum transmitter 1204) and qubits having the second quantum characteristics (e.g., measured by the first quantum receiver 1206) may exist in the same first communication medium 1208. In other words, the second quantum characteristics, as defined by the second quantum transmitter 1209 described hereafter, may be such that bi-directional communication via the first communication medium 1208 may be achieved between the first communication module 1202 and the second communication module 1207. By way of a non-limiting example, time binning techniques, radio frequency (RF) modulation techniques, phase locking to shifted LOs (in the case of continuous variables), measurement using different basis, and/or any measurable physical attribute that may distinguish between an upstream channel and a downstream channel in the bi-directional communication implementations described herein may be used.

The second communication module 1207 may include a second quantum transmitter 1209 configured to generate qubits (e.g., photons or the like). The data of the qubits may be encoded via sets of orthogonal quantum states, including, but not limited to, pairs of photonic polarization states. The pairs of photonic polarization states may include, for example, the rectilinear, diagonal, and circular photonic polarization states as defined above. The second quantum characteristics associated with the qubit generated by the second quantum transmitter 1209 may include the basis of the qubit(s) transmitted by the second quantum transmitter 1209. Although described herein with reference to basis, the present disclosure contemplates that the second quantum characteristics may include the frequency, wavelength, and/or any other quantum characteristic, property, attribute, etc. of the qubits generated and transmitted by the second quantum transmitter 1209 and that the second quantum characteristics may be varied based upon the intended application of the second communication module 1207.

The second communication module 1207 may further include a second quantum receiver 1211 configured to receive (e.g., measure) qubits. Similar to the first quantum receiver 1206, the second quantum receiver 1211 may be configured to measure qubits that are received, via the first communication medium 1208, from the first communication module 1202 (e.g., generated by the first quantum transmitter 1204). The second quantum receiver 1211 may be configured to measure qubits having first quantum characteristics, such as the quantum basis used to encode data, the frequency of the qubits, the wavelength of the qubits, and/or the like.

The first communication medium 1208, as shown in FIG. 12, is further configured to communicably couple the first communication module 1202 and the second communication module 1207 such that communication is provided between the first quantum transmitter 1204 and the second quantum receiver 1211 and between the second quantum transmitter 1209 and the first quantum receiver 1206 via the first communication medium 1208. The first communication medium 1208 may refer to an optical line, fiber, a quantum line, and/or free space over which quantum data or information and particles, such as qubits, are exchanged. These would include quantum communication channels used for applying one or more quantum cryptographic techniques (e.g., QKD) that rely on quantum properties, such as quantum uncertainty, superposition, and/or quantum entanglement. Although the first communication medium 1208 is described herein with reference to a quantum communication channel, the present disclosure contemplates that the techniques described herein may be applicable to any communication channel. Furthermore, although described herein with reference to example embodiments in which the communication channel refers to an optical fiber or free space, the present disclosure contemplates that a communication channel may refer to any mechanism, structure (e.g., or absence thereof), or the like through which quantum information-based communications (e.g., photons, qubits, single or entangled quantum particles, etc.) may propagate or otherwise travel.

In some embodiments, the first communication medium 1208 may include an optical fiber such that communication between the first quantum transmitter 1204 and the second quantum receiver 1211 and communication between the second quantum transmitter 1209 and the first quantum receiver 1206 is provided by the same optical fiber. In other words, a common communication medium is used for bi-directional quantum communication between the first communication module 1202 and the second communication module 1207. In such an embodiment, a transmission of qubits between the first quantum transmitter 1204 and the second quantum receiver 1211 and a transmission of qubits between the second quantum transmitter 1209 and the first quantum receiver 1206 may occur at the same or substantially the same time. Although described herein with reference to an optical fiber implementation, the present disclosure contemplates that the bi-directional quantum communication techniques described herein may also be applicable to instances in which the first communication medium 1208 comprises a free space communication medium.

In an example bi-directional quantum communication operation, the first quantum transmitter 1204 may receive instructions (e.g., from the GPU/CPU 1205 and/or network card described hereafter) to generate and transmit qubits having first quantum characteristics (e.g., basis, frequency, wavelength, etc.). Similarly, the second quantum transmitter 1209 may receive instructions (e.g., from the same GPU/CPU 1205 or another computing device) to generate and transmit qubits having second quantum characteristics (e.g., basis, frequency, wavelength, etc.), one of which is different from the first quantum characteristics. The qubits may be transmitted from the first quantum transmitter 1204 and the second quantum transmitter 1209 to the second quantum receiver 1211 and the first quantum receiver 1206, respectively, via the same optical fiber (e.g., first communication medium 1208). The second quantum receiver 1211 may measure the qubits having the first quantum characteristics to receive the data encoded thereon. The first quantum receiver 1206 may similarly measure the qubits having the second quantum characteristics to receive the data encoded thereon. The present disclosure contemplates that the bi-directional quantum interconnect 1200 may leverage any computing device, GPU/CPU 1205, or the like communicably coupled thereto in order to, in whole or in part, control operation of the first communication module 1202 and the second communication module 1207. Furthermore, in some embodiments, the first quantum transmitter 1204 and/or the second quantum transmitter 1209 may each configured to generated entangled pairs of qubits.

With continued reference to FIG. 12, in some embodiments, the bi-directional quantum interconnect 1200 may employ classical communication channels, such as via optical transceivers. By way of a non-limiting example, the first communication module 1202 may include a first optical transceiver 1201 that is configured to generate optical signals (e.g., via a vertical cavity surface emitting laser (VCSEL) or the like) and receive optical signals (e.g., via a photodiode (PD) or the like). The second communication module 1207 may include a second optical transceiver 1203 that may similarly be configured to generate optical signals (e.g., via a vertical cavity surface emitting laser (VCSEL) or the like) and receive optical signals (e.g., via a photodiode (PD) or the like). These optical signals may also be transmitted via the first communication medium 1208 (e.g., an optical fiber or the like) and be used to, for example, facilitate synchronization between the first communication module 1202 and the second communication module 1207. Although described herein with reference to example synchronization operations, the present disclosure contemplates that a classical communication channel, such as the paired first optical transceiver 1201 and the second optical transceiver 1203, may be used for any operation (e.g., transmission of data between parties, sifting operations, etc.) based upon the intended application of the bi-directional quantum interconnect 1200.

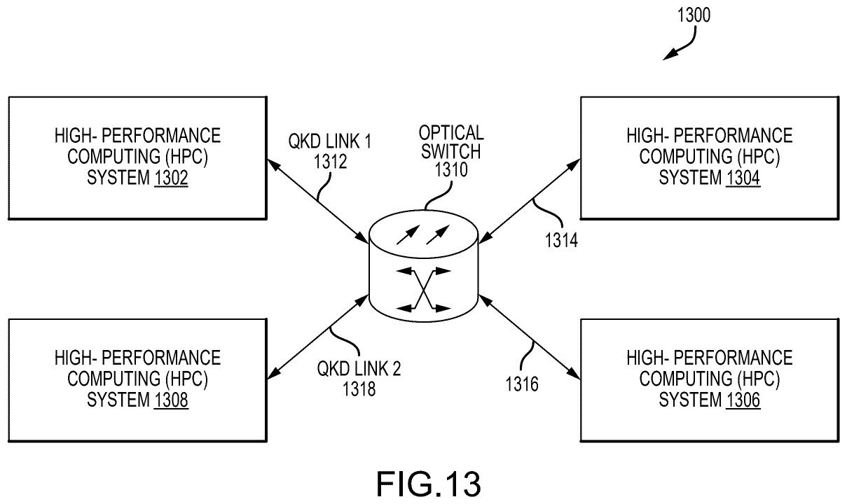

FIG. 13 illustrates a system 1300 that facilitates QKD connectivity between more than two HPC systems according to one or more embodiments of the present disclosure. The system 1300 may include one or more components of system 100 to help improve thermal performance thereof. According to various embodiments, the system 1300 provides a crossbar optical switch to facilitate different connections among HPC systems. In an embodiment illustrated in FIG. 13, the system 1300 includes an HPC system 1302, an HPC system 1304, an HPC system 1306, and/or an HPC system 1308. The system 1300 also includes an optical switch 1310. The optical switch 1310 can be, for example, a crossbar optical switch that includes switches arranged in a matrix configuration to facilitate connections among the HPC system 1302, the HPC system 1304, the HPC system 1306 and/or the HPC system 1308. For example, the optical switch 1310 can include multiple input communication channels and multiple output communication channels that form a crossed pattern of interconnections to facilitate connections among the HPC system 1302, the HPC system 1304, the HPC system 1306, and/or the HPC system 1308.

The HPC system 1302 can be communicatively coupled to the HPC system 1304, the HPC system 1306, and/or the HPC system 1308 via the optical switch 1310. For example, the HPC system 1302 can be communicatively coupled to the optical switch 1310 via a QKD link 1312. Furthermore, the optical switch 1310 can be communicatively coupled to the HPC system 1304 via a QKD link 1314. As such, the HPC system 1302 can be communicatively coupled to the HPC system 1304 via the QKD link 1312, the optical switch 1310, and the QKD link 1314. In another example, the HPC system 1302 can be communicatively coupled to the optical switch 1310 via the QKD link 1312. Furthermore, the optical switch 1310 can be communicatively coupled to the HPC system 1306 via a QKD link 1316. As such, the HPC system 1302 additionally or alternatively can be communicatively coupled to the HPC system 1306 via the QKD link 1312, the optical switch 1310 and the QKD link 1316. In yet another example, the HPC system 1302 can be communicatively coupled to the optical switch 1310 via the QKD link 1312. Furthermore, the optical switch 1310 can be communicatively coupled to the HPC system 1308 via a QKD link 1318. As such, the HPC system 1302 additionally or alternatively can be communicatively coupled to the HPC system 1308 via the QKD link 1312, the optical switch 1310 and the QKD link 1318.

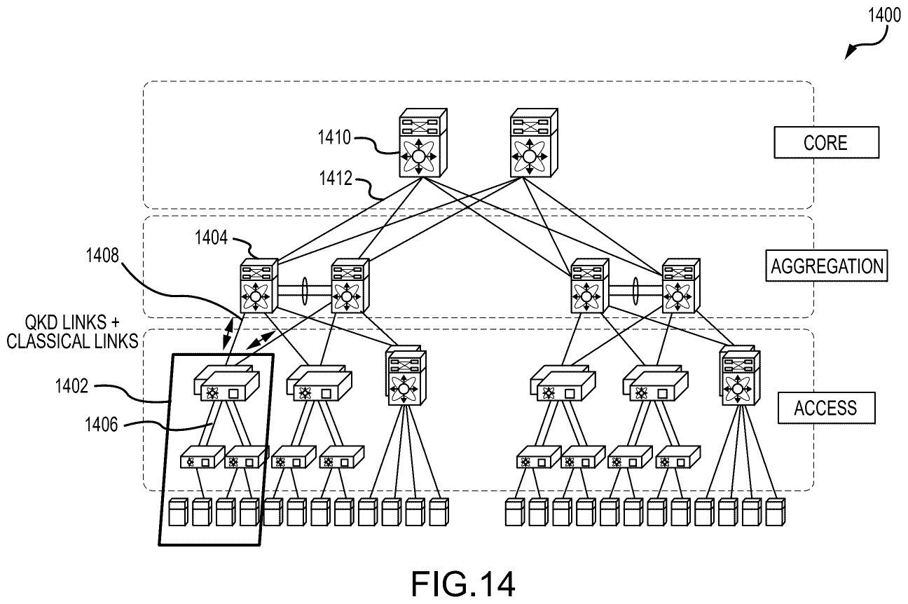

FIG. 14 illustrates a system 1400 that facilitates QKD communication via a fat-tree data center architecture according to one or more embodiments of the present disclosure. The system 1400 may include one or more thermal management components depicted and described herein. According to various embodiments, the system 1400 provides classical links within a computer cluster and QKD links external to the computer cluster. For instance, the system 1400 includes a computer cluster 1402. The computer cluster 1402 includes, for example, a set of connected computers (e.g., a set of connected processor cores, a set of connected servers, and/or a set of connected routers) associated with classical links 1406. Furthermore, the computer cluster 1402 is communicatively coupled to a server 1404 via a QKD link 1408. In certain embodiments, the computer cluster 1402 can be associated with an access layer of a data center network and the server 1404 can be associated with an aggregation layer of the data center network. In one or more embodiments, the server 1404 can be additionally communicatively coupled to a server 1410 via a classical link 1412. In certain embodiments, the server 1410 can be associated with a core layer of the data center network.

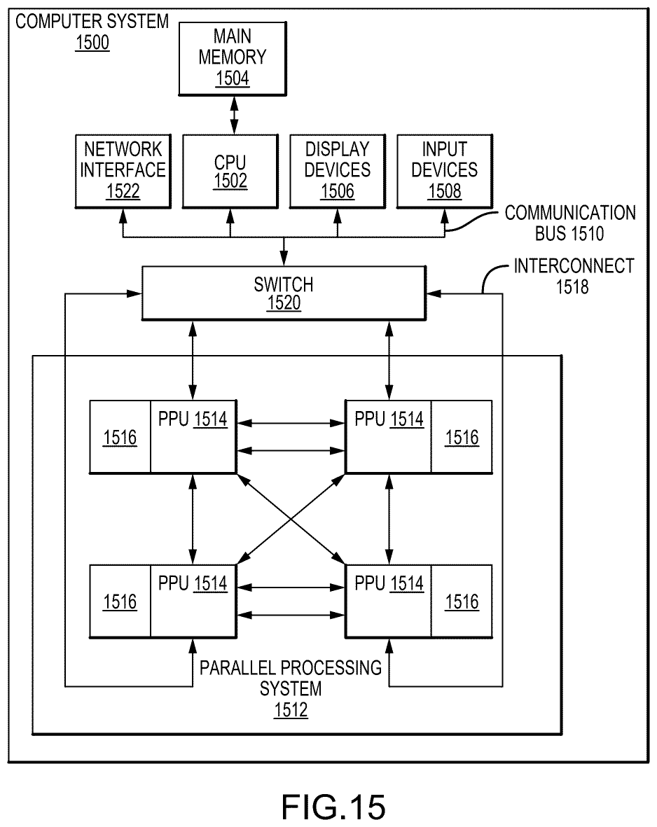

FIG. 15 illustrates a computer system 1500, according to at least one embodiment. In at least one embodiment, computer system 1500 is configured to implement various processes and methods described throughout this disclosure. In particular, the computer system 1500 may be provided with one or more components of system 100 to help improve the thermal performance thereof.

In at least one embodiment, computer system 1500 comprises, without limitation, at least one central processing unit (“CPU”) 1502 that is connected to a communication bus 1510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1500 includes, without limitation, a main memory 1504 and control logic (e.g., implemented as hardware, software, or a combination thereof) and data are stored in main memory 1504 which may take form of random access memory (“RAM”). In at least one embodiment, a network interface subsystem (“network interface”) 1522 provides an interface to other computing devices and networks for receiving data from and transmitting data to other systems from computer system 1500.

In at least one embodiment, computer system 1500, in at least one embodiment, includes, without limitation, input devices 1508, parallel processing system 1512, and display devices 1506 which can be implemented using a conventional cathode ray tube (“CRT”), liquid crystal display (“LCD”), light emitting diode (“LED”), plasma display, or other suitable display technologies. In at least one embodiment, user input is received from input devices 1508 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1504 and/or secondary storage. Computer programs, if executed by one or more processors, enable system 1500 to perform various functions in accordance with at least one embodiment. memory 1504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1502; parallel processing system 1512; an integrated circuit capable of at least a portion of capabilities of both CPU 1502; parallel processing system 1512; a chipset (e.g., a group of integrated circuits designed to work and sold as a unit for performing related functions, etc.); and any suitable combination of integrated circuit(s).

In at least one embodiment, parallel processing system 1512 includes, without limitation, a plurality of parallel processing units (“PPUs”) 1514 and associated memories 1516. In at least one embodiment, PPUs 1514 are connected to a host processor or other peripheral devices via an interconnect 1518 and a switch 1520 or multiplexer. In at least one embodiment, parallel processing system 1512 distributes computational tasks across PPUs 1514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1514, although such shared memory may incur performance penalties relative to use of local memory and registers resident to a PPU 1514. In at least one embodiment, operation of PPUs 1514 is synchronized through use of a command such as_syncthreads( ), wherein all threads in a block (e.g., executed across multiple PPUs 1514) to reach a certain point of execution of code before proceeding.

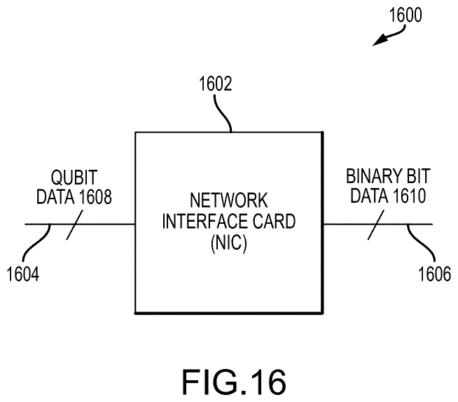

FIG. 16 illustrates a system 1600 according to one or more embodiments of the present disclosure. The system 1600 may include one or more thermal management components depicted and described herein to improve the thermal performance thereof. The system 1600 is illustrated to include a network interface controller (NIC) 1602. The NIC 1602 is, for example, a hardware component (e.g., a network interface controller) configured to connect to a network and/or to facilitate communications within the network. In certain embodiments, the NIC 1602 can be included in and/or can be coupled to a network interface module such as a transceiver device (e.g., an optical transceiver) that facilitates fiber optic communication. In one or more embodiments, the NIC 1602 can be configured to manage transmission of one or more optical signals via an optical fiber. Additionally or alternatively, in one or more embodiments, the NIC 1602 can be configured to control emission of one or more optical signals via a laser.

The NIC 1602, as depicted in FIG. 16, is coupled to a communication channel 1604 and a communication channel 1606. The communication channel 1604 may be a first communication channel associated with quantum communication (e.g., a QKD-based communication). The communication channel 1606 may be a second communication channel associated with classical network communication (e.g., non-QKD-based communication). In one or more embodiments, the communication channel 1606 is an optical communication channel (e.g., a transparent fiber optical connection) that transmits data (e.g., pulses of infrared light) encoded via qubits (e.g., a quantum communication data stream). In one or more embodiments, the communication channel 1606 is an optical communication channel (e.g., a transparent fiber optical connection) that transmits data (e.g., pulses of infrared light) encoded via bits (e.g., a binary data stream). Accordingly, the NIC 1602 can be configured to interface a QKD-based communication medium and a non-QKD-based communication medium. In an embodiment, the NIC 1602 is configured to receive qubit data 1608 via the communication channel 1604. The qubit data 1608 can include, for example, qubits associated with quantum information. Furthermore, in an embodiment, the NIC 1602 is configured to output binary bit data 1610 via the communication channel 1606. The binary bit data 1610 can include, for example, one or more classical binary bits associated with binary information. In one or more embodiments, the communication channel 1604 and/or the communication channel 1606 can be bi-directional. As such, in another embodiment, the NIC 1602 is configured to output the qubit data 1608 via the communication channel 1604. Furthermore, in another embodiment, the NIC 1602 is configured to receive the binary bit data 1610 via the communication channel 1606.

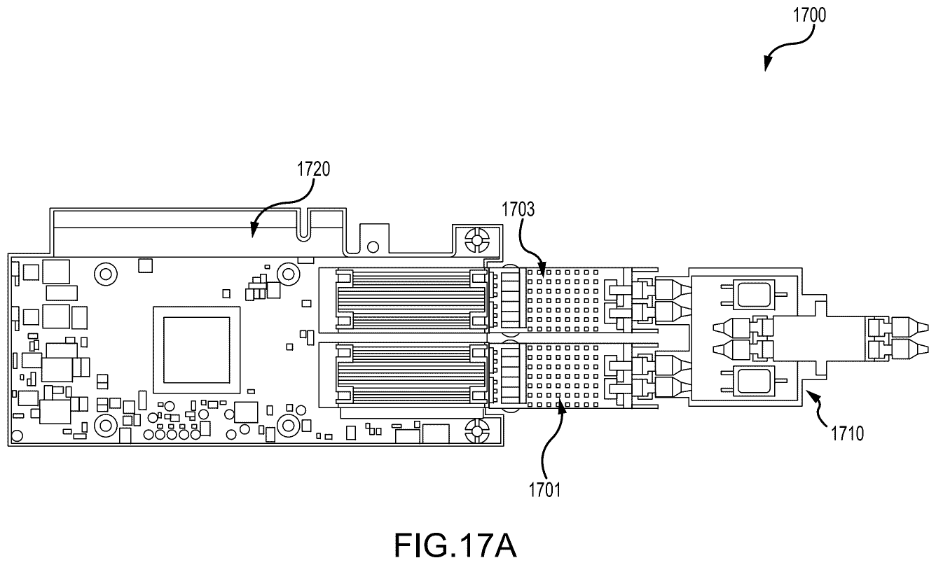

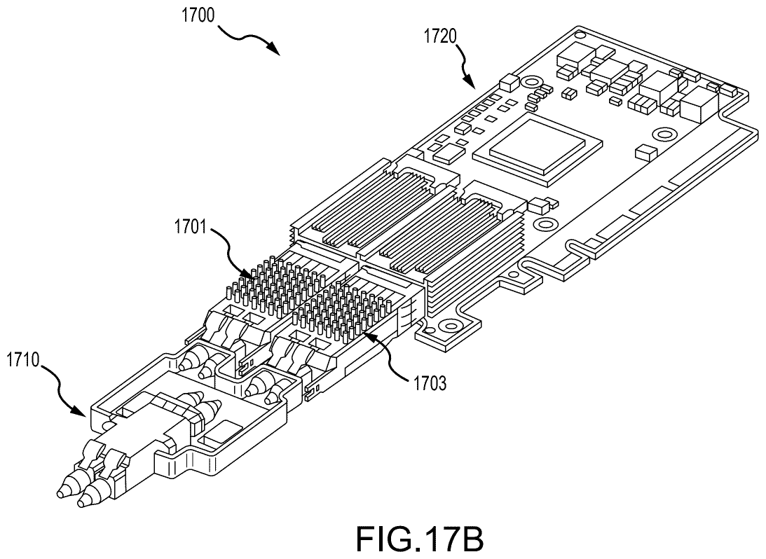

FIGS. 17A and 17B illustrate a top view and a perspective view, respectively, of a transceiver module operatively coupled to a network adapter, in the present example a Network Interface Controller (NIC) 1700, in accordance with an embodiment of the disclosure. As shown in FIGS. 17A and 17B, the transceiver module may correspond to an example of receptacle 108. The NIC 1700 is shown to include a first optical module 1708, a second optical module 1704, an adapter 1716, and a dual-port NIC 1712 of a server. Both the first optical module 1708 and the second optical module 1704 may be dual-fiber transceivers that are configured for duplex communication that allows the source (e.g., server) to communicate with the target (e.g., leaf switch) in both directions. The adapter 1716 may be a ganged physical component configured to link the first optical module 1708 and the second optical module 1704 for the purpose of transmitting and receiving data to and from the leaf switch.

In some embodiments, the adapter 1716 may be configured to operate in two configurations, such as a first configuration and a second configuration. In one aspect, the first configuration may be a default configuration of operation, where the first optical module 1708 may be operationally active. The second configuration may be a contingent configuration that is implemented when the first optical module 1708 operationally fails. When such a failure is detected, the second optical module 1704, which is otherwise operationally inactive or idle, may be engaged become operationally active and handle all network traffic that was initially handled by the first optical module 1708.

In some embodiments, the transceiver module 1700 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1700 may be configured to operate between the server and the leaf layer. In particular, as shown in FIGS. 17A and 17B, the adapter 1716 may be operatively coupled to the first optical module 1708 and the second optical module 1704, while the first optical module 1708 and the second optical module 1704 may be operatively coupled to a dual-port NIC 1712 of a server.

In embodiments, NIC 1700 may comprise one or more processing circuits, as detailed above; the processing circuits may comprise FW, that is loaded according to the techniques described above.

As discussed herein, the example embodiment is described with reference to a pluggable connector such as an octal small form factor pluggable (OSFP); however the embodiments of the present disclosure may equally be applicable to a Quad Small Form-factor Pluggable (QSFP) connector as the cable connector or any connector (e.g., Small Form Pluggable (SFP), C-Form-factor Pluggable (CFP), and the like). Moreover, the embodiments of the present disclosure may also be used with any cable (e.g., passive copper cable (PCC), active copper cable (ACC), or the like) or interconnect utilized by data center racks and associated switch modules (e.g., an active optical module (AOM), QSFP transceiver module, or the like).

Additionally, as discussed herein, the example embodiment is described with reference to a vertical-cavity surface-emitting laser (VCSEL) as an element of a transceiver system; however, embodiments of the present disclosure may be equally applicable for use with any transceiver system and/or element. Still further, as discussed herein, the example embodiment is described with reference to a switch module configured to receive a cage receptacle assembly to allow signals to pass between a cable connector and the switch module. The present disclosure, however, contemplates that a network interface, a high-capacity adapter, or any other applicable networking interface may equally be used instead or in conjunction with the switch module to receive the cage receptacle.

Embodiments of the present disclosure are contemplated to be deployed in a data center environment. While embodiments will be described in connection with certain examples of data center environments, it should be appreciated that embodiments of the present disclosure are not so limited. Indeed, embodiments of the present disclosure contemplate the ability to deploy a cage receptacle assembly in any number of environments including a data center environment or any other suitable environment in which machine-to-machine communications are facilitated.

Illustrative data center environments and components are shown and will now be described with reference to FIGS. 18A through 19B. Data centers, high performance computing clusters, and/or the like are often formed of various computing components or networked devices, and communication networks formed of electrical and/or optical devices may be used to enable communication between the networked devices forming these implementations. As shown in FIGS. 18A, 18B, and 18C, for example, a network architecture 1800 may include a data center 1802, a communication network 1804, and network device(s) 1806. The network architecture 1800 may illustrate a general computing architecture within which more specific systems and/or subsystems may function. Although described hereinafter with reference to a network architecture and/or data center 1802 within which the embodiments of the present disclosure may be implemented, the present disclosure contemplates that the transceiver resiliency devices and techniques described herein may be applicable to any communication implementation without limitation.

For example, the data center 1802 may be a centralized facility designed to house computing resources and related components. The data center 1802 may operate to support the infrastructure required for advanced computational tasks, for efficient, secure, and reliable operations. The data center 1802 may include the building and structural components, including power supplies, cooling systems, fire suppression systems, and physical security measures that are configured to maintain optimal operating conditions and/or protect the equipment from environmental hazards and unauthorized access. An example data center 1802 may include high-performance servers or compute nodes, often arranged in racks, such as those illustrated in FIG. 18B, and connected through high-speed networks as described herein. These servers may include processors (e.g., central processing units (CPUs), graphics processing units (GPUs), data processing units (DPUs) and/or the like), quantum processing units (QPUs), a plurality of parallel processing units (PPUs), and application-specific integrated circuits (ASICs). memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

The data center 1802 may include high-speed network equipment, such as network switches, routers, firewalls, and/or the like to facilitate fast and secure data transmission within the data center 1802 (e.g., between the servers or compute nodes) and between external networks. The data center 1802 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the data center 1802 may support high-performance computing tasks. Examples of various network topologies may include hierarchical networking topologies such as the fat tree topology, Slim Fly topology, Dragonfly topology, and/or the like. The data center 1802 may adhere to a networking topology (e.g., a hierarchal networking topology), such as a fat tree topology, a Slim Fly topology, a Dragonfly topology, and/or the like. The data center 1802 routes traffic amongst the network switches and servers therein, and at least one layer of the topology in the data center 1802 is coupled to the communication network 1804 to allow networking traffic to flow between the data center 1802 and the network device(s) 1806.

The communication network 1804 may communicably couple the data center 1802 with network device(s) 1806 and other external devices for data exchange and connectivity. Examples of the communication network 1804 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 1804 to incorporate multiple network types and configurations may allow the data center 1802 to adapt to diverse application needs, from general data communication to specialized HPC tasks. As described herein, the communication network 1804 may leverage various optical components to establish communication links (e.g., communicably couple) between components in the architecture 1800. As such, the communication network 1804 may include various optical devices, transceivers, modules, and/or the like that are configured to generate optical signals (e.g., provide optical transmitter functionality) and/or receive optical signals (e.g., provide optical receiver functionality).

The network device(s) 1806 may include a variety of computing devices capable of transmitting and receiving signals over the communication network 1804. The network device(s) 1806 may range from personal computing devices to complex server configurations. Examples include Personal Computers (PCs), laptops, tablets, smartphones, and servers. The network device(s) 1806 may facilitate user interactions with the data center 1802, allowing for data input, retrieval, and processing from remote locations. In addition to individual computing devices, the network device(s) 1806 may also include collections of servers or additional data centers. For instance, these could be other data centers similar to or the same as data center 1802. Such an interconnection may allow for the formation of a distributed computing environment for improved redundancy, load balancing, and disaster recovery capabilities. By linking multiple data centers, the network architecture 1800 may leverage geographically dispersed resources, optimizing performance and ensuring high availability.

As described herein, the data center 1802 and/or the network device(s) 1806 may include storage devices and processing circuitry for executing computing tasks, such as controlling the flow of data internally and over the communication network 1804. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry 1818 may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the data center 1802 and network device(s) 1806 may include one or more communication interfaces for facilitating wired and/or wireless communication between one another and other unillustrated elements of the network architecture 1800. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 1800.

Furthermore, the present disclosure contemplates that the network architecture 1800 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 1800 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 1800.

In high-capacity data center networks, the communication network 1804 may leverage optical transceivers that transmit and receive optical signals over optical fibers or other optical communication mediums to establish connection between devices in the architecture 1800.

As shown in FIG. 18C, in one specific but non-limiting example, the communication network 1804 is a network that enables data transmission between the devices 1806a and 1806b using data signals (e.g., digital, optical, wireless signals).

Each type of network offers specific advantages tailored to different operational requirements. For instance, an IP network or Ethernet network may provide widespread compatibility and ease of integration, supporting various protocols and applications across the data center 1802 and the network device(s) 1806 (and/or external devices). An InfiniBand network may offer high throughput and low latency, ideal for HPC environments where rapid data transfer and minimal delay are required. Fibre Channel networks may be employed for their robust performance in storage area networks (SANs), ensuring fast and reliable access to storage resources. Cellular and wireless communication networks may be used to extend connectivity to remote or mobile devices for increased flexibility and accessibility.

As noted above, the network devices 1806a, 1806b may include one or more of Personal Computer (PC), a laptop, a tablet, a smartphone, a server, a collection of servers, and/or any suitable computing device for sending and receiving signals over the communication network 1804. In at least one example embodiment, the one or more network devices 1806 correspond to another data center, similar to or the same as data center 1802.

Each network device 1806 may be provided with transmitter functionality 1810, receiver functionality 1812, and/or transceiver functionality 1814. The transmitter functionality 1810, receiver functionality 1812, and/or transceiver functionality 1814 may include hardware and/or software to support the sending and/or receiving of data across the communication network 1804, through one or more communication channels 1808, for example.

A network device 1806 may also include a digital data source 1816 and/or processing circuitry 1818 to support interactions within the transceiver 1814 or to support interactions between components of the transceiver 1814 and other components of the device 1806. For instance, the processing circuitry 1818 may be included in the transceiver 1814 as illustrated or may be external to the transceiver 1814, without departing from the scope of the present disclosure.

With reference now to FIGS. 19A and 19B, various topologies for use in a data center 1802 will be described in accordance with at least some embodiments of the present disclosure. FIG. 19A illustrates a fat tree topology 1900 for a data center 1802, in accordance with embodiments of the disclosure. However, it is to be understood that the present disclosure is not limited to a fat tree topology. Other network topologies may also be contemplated within the scope of the disclosure. Examples of such alternative topologies include, but are not limited to, Slim Fly topology, which is designed to reduce the number of hops and cable lengths between nodes; Dragonfly topology, which aims to enhance network scalability and reduce latency through a hierarchical group of interconnected switches; and other hierarchical or non-hierarchical topologies that may be optimized for specific performance, scalability, or cost considerations.

The principles and innovations disclosed herein can be applied to these and other network topologies to achieve similar advantages and benefits. Any modifications, variations, or adaptations of the network topologies that fall within the spirit and scope of the present disclosure are considered to be encompassed by this disclosure. In related art systems, a fat tree topology may use the same electrical switching devices on all layers (edge, aggregation, core). For example, each switching device may be 1U switch, where 1U refers to the industry standard size for rack-mounted switch and/or server. The interconnection between switches of different layers may be accomplished with optical links using active optical cables and optical transceivers implemented in a pluggable form factor (also referred to as “pluggables”).

As shown in FIG. 19B, the fat tree topology may include three distinct layers: the edge layer 1902, the aggregation layer 1904, and the core layer 1906. The edge layer 1902, located at the bottom of the hierarchy, incorporates Top-of-Rack (ToR) switches. The edge layer 1902 may serve as the initial point of aggregation for traffic originating from the servers. The servers and server racks are generally connected to the edge layer 1902, although they are not illustrated in the figure. The edge layer 1902 may include a plurality of switches, designated as ELS1, ELS2, . . . , ELSn, as shown in FIG. 19B. The aggregation layer 1904 may be positioned above the edge layer 1902 and may further consolidate traffic from multiple edge layer switches ELS1, ELS2, . . . , ELSn. The aggregation layer 1904 may be composed of switches 1908, which may include switches ALS1, ALS2, . . . , ALSo. The aggregation layer switches may be configured to aggregate data traffic from the edge layer 1902, ensuring efficient load balancing and data flow management. At the top of the hierarchy is the core layer 1906, which may provide high-speed interconnectivity and enables communication among different racks within the data center 1802. The core layer 1906 may include a series of switches labeled as CLS1, CLS2, . . . , CLSm. These core layer switches may be configured to ensure that data can traverse the network 1910 quickly and efficiently, minimizing latency and maximizing bandwidth.

Optical Data center Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

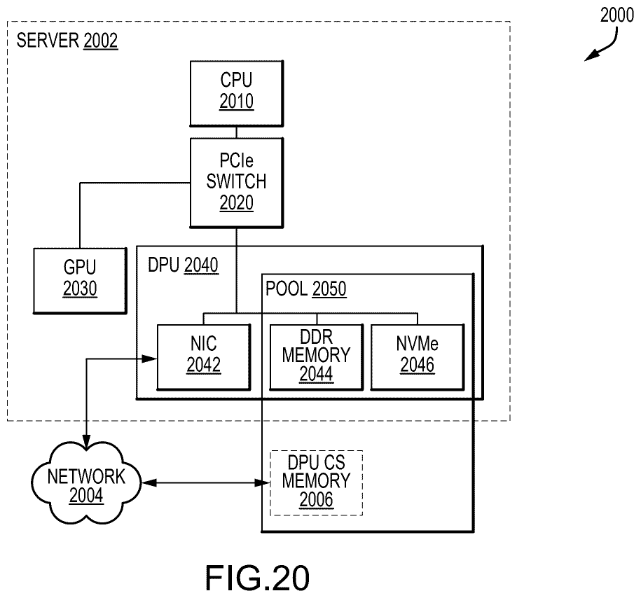

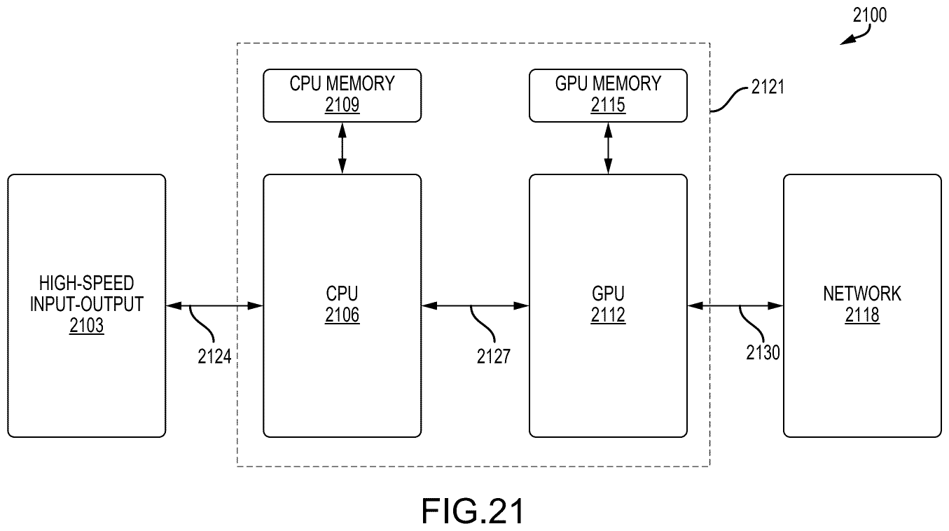

FIG. 20 illustrates an example data center rack 2000, or cabinet that is designed to house servers, networking devices, modules, and other data center 1802 computing equipment and used in conjunction with optical fibers 2008.

Accordingly, various different types of cable connectors 2004, which may correspond to an example of an pluggable transceiver module 120, also exist for enabling transmission of signals (optical and/or electrical) between switch modules 2012 and other equipment in a data center 1802. For example, OSFP connectors and cables, as well as other forms of connectors such as QSFP, Small Form Pluggable (SFP), and C-Form-factor Pluggable (CFP) connectors provide high-speed information operations interface interconnects. Regardless of the type of cable connectors, these transceivers may interface a switch system board, such as a motherboard in a switch system, to a fiber optic or copper networking cable, such as by making connections between switch modules 2012 as shown in FIG. 20.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more embodiments, configurations, or aspects for the purpose of streamlining the disclosure. The features of the embodiments, configurations, or aspects of the disclosure may be combined in alternate embodiments, configurations, or aspects other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the disclosure.

Moreover, though the description of the disclosure has included description of one or more embodiments, configurations, or aspects and certain variations and modifications, other variations, combinations, and modifications are within the scope of the disclosure, e.g., as may be within the skill and knowledge of those in the art, after understanding the present disclosure. It is intended to obtain rights, which include alternative embodiments, configurations, or aspects to the extent permitted, including alternate, interchangeable and/or equivalent structures, functions, ranges, or steps to those claimed, whether or not such alternate, interchangeable and/or equivalent structures, functions, ranges, or steps are disclosed herein, and without intending to publicly dedicate any patentable subject matter.

It is to be appreciated that any feature described herein can be claimed in combination with any other feature(s) as described herein, regardless of whether the features come from the same described embodiment.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” and “A, B, and/or C” means A alone, B alone, C alone, A and B together, A and C together, B and C together, or A, B, and C together. When each one of A, B, and C in the above expressions refers to an element, such as X, Y, and Z, or a class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

It should be understood that every maximum numerical limitation given throughout this disclosure is deemed to include each and every lower numerical limitation as an alternative, as if such lower numerical limitations were expressly written herein. Every minimum numerical limitation given throughout this disclosure is deemed to include each and every higher numerical limitation as an alternative, as if such higher numerical limitations were expressly written herein. Every numerical range given throughout this disclosure is deemed to include each and every narrower numerical range that falls within such broader numerical range, as if such narrower numerical ranges were all expressly written herein.

What is claimed is:

1. A system, comprising:
one or more cages; and
a cold plate attached to the one or more cages, wherein the one or more cages are attached to the cold plate with one or more fasteners.

2. The system of claim 1, wherein the cold plate comprises one or more conduits through which a heat transfer fluid is allowed to pass.

3. The system of claim 1, wherein the one or more fasteners comprises a screw.

4. The system of claim 1, further comprising:
a Thermal Interface Material (TIM) placed between the one or more cages and the cold plate, and wherein the TIM comprises at least one of a grease, elastomeric pad, tape, film, phase change material, gel, adhesive, and paste.

5. The system of claim 1, wherein the one or more cages comprise a plurality of cages.

6. The system of claim 1, wherein the one or more cages are provided on a front panel of a network device and are configured to accept a pluggable transceiver module therein, wherein the network device comprises at least one of a switch and a network adapter and wherein the pluggable transceiver module comprises a connector plug, and wherein the connector plug comprises at least one of a QSFP plug and an OSFP plug.

7. The system of claim 1, further comprising:
a Printed Circuit Board (PCB) provided in the cold plate, wherein the PCB is press-fit into a recess of the cold plate.

8. The system of claim 1, wherein the one or more cages comprise a top cage and a bottom cage and wherein the cold plate is sandwiched between the top cage and the bottom cage.

9. A network device, comprising:
one or more cages configured to receive a pluggable transceiver module; and
a cold plate attached to the one or more cages in an arrangement that facilitates a transfer of heat away from the one or more cages.

10. The network device of claim 9, wherein the cold plate comprises one or more conduits through which a heat transfer fluid is allowed to pass.

11. The network device of claim 9, further comprising:
a Printed Circuit Board (PCB) embedded in a recess of the cold plate.

12. The network device of claim 9, wherein the cold plate is screwed to the one or more cages.

13. The network device of claim 9, wherein the one or more cages are provided at a front panel.

14. The network device of claim 9, wherein the pluggable transceiver module comprises at least one of a QSFP plug and an OSFP plug.

15. The network device of claim 9, wherein the one or more cages comprise a top cage and a bottom cage and wherein the cold plate is sandwiched between the top cage and the bottom cage.

16. A liquid-cooled switch, comprising:
one or more cages configured to receive a pluggable transceiver module; and
a cold plate attached to the one or more cages, wherein the one or more cages are attached to the cold plate with one or more fasteners and wherein the cold plate comprises one or more conduits through which a heat transfer fluid is allowed to pass.

17. The liquid-cooled switch of claim 16, wherein the one or more fasteners comprise a screw, wherein the one or more conduits comprise a plurality of conduits, and wherein the one or more fasteners are positioned between the plurality of conduits.

18. The liquid-cooled switch of claim 16, further comprising:
a Printed Circuit Board (PCB) embedded in a recess of the cold plate, wherein the PCB is press-fit into the recess of the cold plate.

19. A switch, comprising:
one or more receptacles configured to exchange data via optical signals; and
a cold plate attached to a bottom side of the one or more receptacles with one or more fasteners such that the cold plate facilitates a transfer of heat away from the one or more receptacles.

20. The switch of claim 19, further comprising:
a Printed Circuit Board (PCB) embedded in a recess of the cold plate, wherein the PCB is press-fit into the recess of the cold plate, and wherein the cold plate is manufactured with a different tolerance than the PCB.
